(19) United States
(12) Patent Application Publication
(10) Pub. No.: US 2026/0018537 A1
(43) Pub. Date: Jan. 15, 2026

(54) SEMICONDUCTOR DEVICE AND METHOD OF MANUFACTURING THE SAME

(71) Applicant: Renesas Electronics Corporation, Tokyo (JP)

(72) Inventor: Takao KANEKO, Tokyo (JP)

(21) Appl. No.: 19/208,741

(22) Filed: May 15, 2025

(30) Foreign Application Priority Data
Jul. 10, 2024 (JP) 2024-111127

(51) Int. Cl. H01L 23/00; H01L 21/48; H01L 21/56; H01L 23/16; H01L 23/31; H01L 23/498

(52) U.S. Cl. CPC H01L 23/562; H01L 21/4853; H01L 21/4864; H01L 21/563; H01L 23/16; H01L 23/3185; H01L 23/49816; H01L 23/49822; H01L 24/16; H01L 2224/16227; H01L 2924/18161; H01L 2924/3511

(57) ABSTRACT

A semiconductor device includes a wiring substrate having an upper surface, a semiconductor chip mounted on the wiring substrate, and a stiffener ring fixed onto the wiring substrate via a plurality of adhesive layers. The upper surface is a quadrangular shape, and first and second center lines and first and second diagonal lines can be drawn. The stiffener ring has four extension portions and four corner portions. Adhesive layers include first, second, third and fourth adhesive layers that respectively overlap with the four extension portions and that are arranged at a portion overlapping with one of the first center line and the second center line. Also the adhesive layers include fifth, sixth, seventh, and eighth adhesive layers that respectively overlap with the four corner portions and that are arranged at a portion overlapping with one of the first diagonal line and the second diagonal line.

### CROSS-REFERENCE TO RELATED APPLICATIONS

The present application claims priority from Japanese Patent Application No. 2024-111127 filed on Jul. 10, 2024, the content of which is hereby incorporated by reference to this application.

### BACKGROUND

The present invention relates to a semiconductor device and a method of manufacturing the same.

There are disclosed techniques listed below.
[Patent Document 1] Japanese Unexamined Patent Application Publication No. 2003-51568
[Patent Document 2] Japanese Unexamined Patent Application Publication No. 2014-130961

In a semiconductor device in which a semiconductor chip is mounted on a wiring substrate, there is a technique of mounting, on the wiring substrate, a board (stiffener ring) for reinforcing the wiring substrate (see, for example, Patent Document 1 and Patent Document 2).

### SUMMARY

A function to suppress warpage deformation of the wiring substrate is demanded about the stiffener ring mounted on the wiring substrate. The stiffener ring is fixed on the wiring substrate via an adhesive layer. As a method of ensuring an adhesive strength necessary for suppressing the warpage deformation of the wiring substrate, a structure in which the adhesive layer is continuously arranged all around the stiffener ring is conceivable.

Meanwhile, for example, from a viewpoint of reducing a material usage amount of the adhesive layer, it is preferable that there are a region in which the adhesive layer is sandwiched between the stiffener ring and the wiring substrate and a region in which the adhesive layer is not sandwiched therebetween.

Other problems and novel features will be apparent from the description of the present specification and the accompanying drawings.

A semiconductor device according to one embodiment includes a wiring substrate having an upper surface, a semiconductor chip mounted on the upper surface of the wiring substrate, and a stiffener ring fixed onto the upper surface of the wiring substrate via a plurality of adhesive layers separated from each other. The upper surface is a quadrangular shape, and can draw a first center line and a second center line, and a first diagonal line and a second diagonal line. The stiffener ring has four extension portions and four corner portions. The plurality of adhesive layers includes four adhesive layers that overlap with each of the four extension portions and that are arranged at a portion that is overlapping with one of the first center line and the second center line. In addition, the plurality of adhesive layers includes another four adhesive layers that overlap with each of the four corner portions and that are arranged at a portion that is overlapping with one of the first diagonal line and the second diagonal line.

A method of manufacturing a semiconductor device according to another embodiment includes (a) mounting a semiconductor chip on an upper surface of a wiring substrate, and (b) mounting a stiffener ring on a first region of the upper surface of the wiring substrate. The (b) includes (b1) applying adhesive materials onto a plurality of portions of the first region, (b2) arranging the stiffener ring on the first region and bonding the stiffener ring via the adhesive materials, (b3) curing the adhesive materials to make the curing adhesive materials a plurality of adhesive layers separated from each other, thereby fixing the stiffener ring onto the wiring substrate. The upper surface is a quadrangular shape, and can draw the first center line and the second center line and the first diagonal line and the second diagonal line. The first region has four extension portions and four corner portions. In the (b1), the plurality of adhesive materials applied so as to be separated from each other includes four adhesive materials that overlap with each of the four extension portions and that are applied at a portion that is overlapping with one of the first center line and the second center line. In addition, the plurality of adhesive materials includes another four adhesive materials that overlap with each of the four corner portions and that are applied at a portion that is overlapping with one of the first diagonal line and the second diagonal line.

According too the above embodiments, performance of the semiconductor device can be improved.

### BRIEF DESCRIPTION OF THE DRAWINGS

FIG. 1 is an upper view of a semiconductor device according to one embodiment.

FIG. 2 is a lower view of the semiconductor device shown by FIG. 1.

FIG. 3 is a cross-sectional view taken along line A-A of FIG. 1.

FIG. 4 is a perspective plan view showing an adhesive layer between a stiffener ring and a wiring substrate by passing through the stiffener ring shown by FIG. 1.

FIG. 5 is an explanatory diagram schematically showing a relationship between a direction, in which the wiring substrate is transformed, and the stiffener ring mounted on the wiring substrate.

FIG. 6 is a plan view showing a state in which the stiffener ring shown by FIG. 1 and the adhesive layer are removed.

FIG. 7 is a plan view showing a modification example with respect to FIG. 4.

FIG. 8 is a plan view showing a semiconductor device that is a modification example with respect to FIG. 1.

FIG. 9 is an explanatory diagram of the semiconductor device shown by FIG. 8.

FIG. 10 is a perspective plan view showing an adhesive layer between the stiffener ring and the wiring substrate by passing through the stiffener ring shown by FIG. 8.

FIG. 11 is a perspective plan view showing a modification example with respect to FIG. 10.

FIG. 12 is a plan view showing another modification example with respect to FIG. 1.

FIG. 13 is an explanatory diagram showing a flow example of an assemble step of the semiconductor device according to the embodiment.

FIG. 14 is an explanatory diagram showing a modification example of the wiring substrate prepared by a wiring substrate preparing step shown by FIG. 13.

FIG. 15 is a plan view showing a state in which an adhesive material is applied on the wiring substate in an adhesive material applying step shown by FIG. 13.

FIG. 16 is a plan view showing a modification example with respect to FIG. 15.

### DETAILED DESCRIPTION

### (Explanation of Description Format, Basic Terms, and Usage in Present Application)

In the present application, a description of embodiments is made by dividing them into a plurality of sections or the like when required as a matter of convenience. However, these sections are not irrelevant to each other unless otherwise stated, and the one relates to the entire or a part of the other as a modification example, details, or a supplementary explanation thereof. In addition, a repetitive explanation of the similar descriptions will be omitted as principle. Further, each component of the embodiments is not essential except for a case of being otherwise stated, a case of theoretically being limited to such a number, and a case of not being so apparently from context.

Similarly, in the description of the embodiments, the phrase “X made of A” for a material, a composition or the like is not intended to exclude those containing elements other than A unless otherwise specified and except for the case where it clearly contains only A from the context. For example, as for a component, it means “X containing A as a main component”. For example, a “silicon member” or the like is not limited to pure silicon and it is obvious that the silicon member includes a member made of silicon germanium (SiGe) alloy, a member made of multicomponent alloy containing silicon as a main component, and a member containing other additives or the like. In addition, gold plating, a Cu layer, nickel plating or the like includes a member containing gold, Cu, nickel or the like as a main component as well as a pure one unless otherwise indicated clearly.

In addition, when referring to a specific value or amount, a value or amount larger or smaller than the specific value or amount is also applicable unless otherwise stated or except for the case where the value or amount is logically limited to the specific value or amount and the value or amount is apparently limited to the specific value or amount from the context.

In addition, the description of the same or similar portions is not repeated in principle unless particularly required in the following embodiments.

in the attached drawings, hatching may be omitted even in cross sections in the case where it becomes rather complicated or the case where discrimination from void is clear. In this regard, when it is clear from the description or the like, an outline of a background may be omitted even in a planarly closed hole. Furthermore, even other than the cross section, hatching or dot patterns may be drawn so as to clarify non-voids or clarify a boundary of regions.

### <Semiconductor Device>

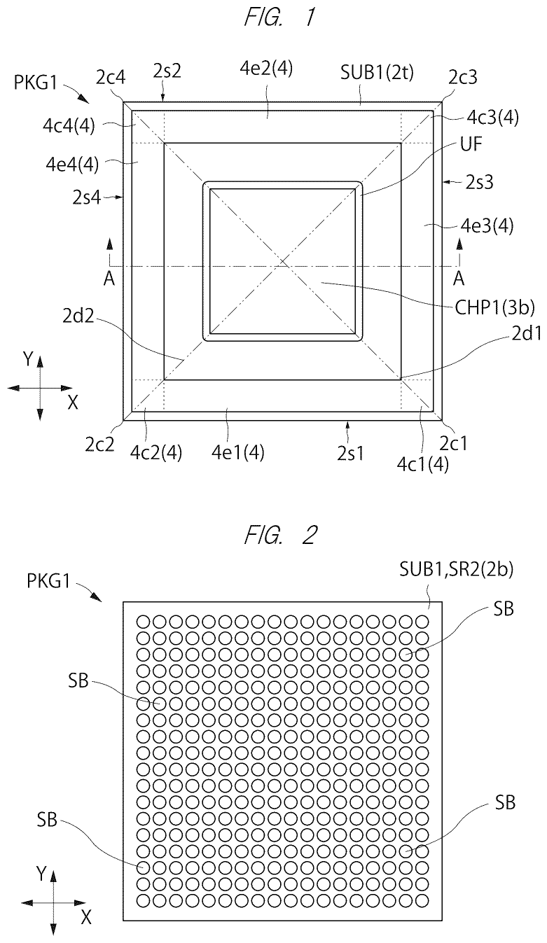

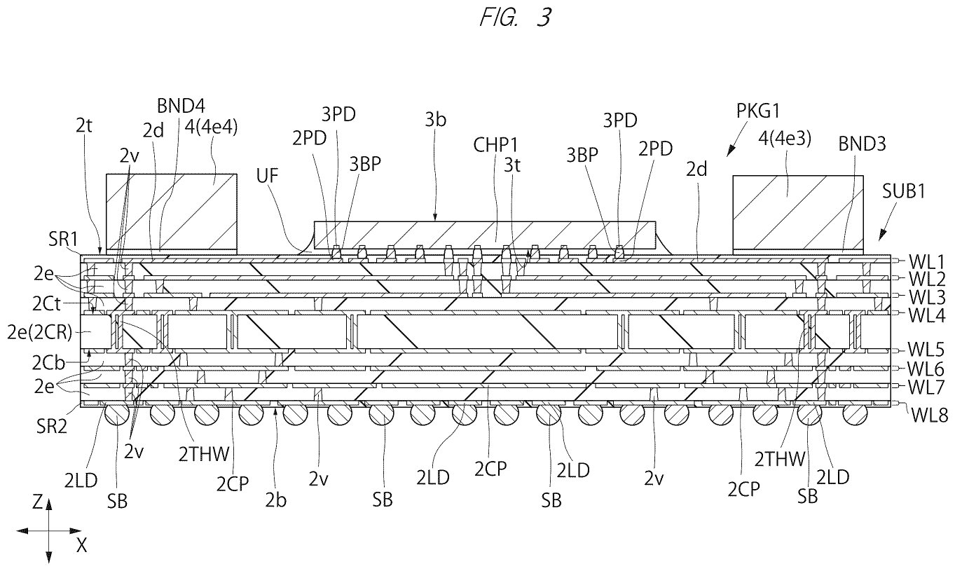

FIG. 1 is an upper view of a semiconductor device according to one embodiment. FIG. 2 is a lower view of the semiconductor device shown by FIG. 1. FIG. 3 is a cross-sectional view taken along A-A line of FIG. 1. FIG. 1 shows, by dotted lines, an outline of a semiconductor chip CHP1 covered with a stiffener ring 4.

In FIG. 1 to FIG. 3, any of an X direction (see FIG. 1 to FIG. 3), a Y direction (see FIG. 1 and FIG. 2), and a Z direction (see FIG. 3) is described. The Y direction is a side intersecting with the X direction, and the X direction and the Y direction are orthogonal to each other in explanation made below. The Z direction is a direction orthogonal to the respective X direction and Y direction. In other words, the Z direction is a normal direction with respect to an X-Y plan including the X direction and the Y direction. In the explanation made below, a “thickness” means a length of the Z direction in principle. In addition, in the explanation made below, a “plan view” means a plan view viewed from the X-Y plan in principle.

A semiconductor device PKG1 according to the present embodiment has a wiring substrate SUB1, and a semiconductor chip CHP1 (see FIG. 3) mounted on the wiring substrate SUB1. In addition, the semiconductor device PKG1 has a stiffener ring 4 arranged so as to continuously surround a periphery of the semiconductor chip CHP1 in a plan view.

Recently, with sophisticated functions of the semiconductor device, there is a tendency in which a plane size of the wiring substrate SUB1 becomes larger. When the plane size of the wiring substrate SUB1 becomes larger, occurrence of the warpage deformation at the wiring substrate SUB1 may be increased. For example, this is because a stress applied to the wiring substrate SUB1 due to a temperature cycle load increases in proportion to a length of a diagonal line of the wiring substrate SUB1.

In a case of the present embodiment, as a member for suppressing the warpage deformation of the wiring substrate SUB1, the stiffener ring 4 is mounted on the wiring substrate SUB1.

Hereinafter, details of the semiconductor device PKG1 will be explained in order.

The wiring substrate SUB1 that the semiconductor device PKG1 has includes, as shown in FIG. 3, an upper surface 2t that is a chip mounting surface, and a lower surface 2b opposite to the upper surface 2t. The lower surface 2b functions as an implementation surface of the semiconductor device PKG1.

The wiring substrate SUB1 that the semiconductor device PKG1 has an internal interface terminal (pad 2PD) exposed from an insulation film SR1 on the upper surface 2t, and an external interface terminal (land 2LD) exposed from an insulation film SR2 on the lower surface 2b that is the implementation surface.

In addition, the wiring substrate SUB1 has a plurality of wiring layers electrically connecting the internal interface terminal and the exterior interface terminal. In an example shown by FIG. 3, the wiring substrate SUB1 is a wiring substrate having an eight-layer structure that includes a wiring layer WL1, a wiring layer WL2, a wiring layer WL3, a wiring layer WL4, a wiring layer WL5, a wiring layer WL6, a wiring layer WL7, and a wiring layer WL8. However, the number of wiring layers of the wiring substrate SUB1 is not limited to eight layers, and may be seven layers or less or may be nine layers or more.

Each wiring layer is between the upper surface 2t and the lower surface 2b. Each wiring layer has a conductor pattern such as a wring which is a path for supplying an electrical signal and power. The respective wiring layers are electrically connected to each other via a via wiring 2v, which is an interlayer conductive path penetrating through an insulation layer 2e, or via a through-hole wiring 2THW. The insulation layer 2e is arranged between the respective wiring layers. A plurality of insulation layers 2e arranged between the respective wiring layers include a core insulation layer (insulation layer, core material, core insulation layer) 2CR arranged between the upper surface 2t and the lower surface 2b. The core insulation layer 2CR is made of a core material for ensuring rigidity of the wiring substrate SUB1, for example, a prepreg resin-impregnated in a glass fiber.

The wiring layer WL1, which is arranged closest to the upper surface 2t, among the plurality of wiring layers is covered with the insulation film SR1. The insulation film SR1 is provided with an opening, and each of a plurality of pads 2PD provided on the wiring layer WL1 is exposed from the insulation film SR1 in the opening.

The wiring layer WL8, which is arranged at the closest portion to a lower surface 2b side of the wiring substrate SUB1, among the plurality of wiring layers is provided with a plurality of lands 2LD. The wiring layer WL8 is covered with an insulation film SR2. Each of the insulation film SR1 and the insulation film SR2 is a solder resist film made of an organic material(s) capable of suppressing solder wetting and spreading. The plurality of pads 2PD provided on the wiring layer WL1 and the plurality of lands 2LD provided on the wiring layer WL8 are respectively electrically connected to one another via the conductor pattern (wiring 2d and large-area conductor pattern 2CP), the via wiring 2v, and the through-hole wiring 2THW, the conductor pattern being formed in each wiring layer that the wiring substrate SUB1 has.

Each of the wiring 2d, the pad 2PD, the via wiring 2v, a via land (omitted in the figure), a through-hole land (omitted in the figure), the through-hole wiring 2THW, the land 2LD, and the conductor pattern 2CP is made of, for example, copper or a metal material mainly containing copper.

The wiring substrate SUB1 is formed by, for example, laminating the plurality of wiring layers on each of an upper surface 2Ct and a lower surface 2Cb of the core insulation layer (insulation layer, core material, core insulation layer) 2CR by a build-up method. In addition, the wiring layer WL4 on an upper surface 2Ct side of the core insulation layer 2CR and the wiring layer WL5 on a lower surface 2Cd side thereof are electrically connected to each other via the plurality of through-hole wirings 2THW that are embedded in the plurality of through-hole provided so as to penetrate from one of the upper surface 2Ct and the lower surface 2Cb to the other.

In addition, in the example shown by FIG. 3, a plurality of solder balls (solder material, external terminal, electrode, external electrode) SB are formed on the lower surface 2b of the wiring substrate SUB1. Specifically, the solder ball SB is connected to each of the plurality of lands 2LD of the wiring substrate SUB1. When the semiconductor device PKG1 is implemented on a not-shown mother board, the solder ball SB is a conductive member that electrically connects a plurality of terminals (omitted in the figure) on a mother board side and the plurality of lands 2LD. The solder ball SB is, for example, a Sn—Pb solder material containing lead (Pb) or a solder material made of so-called lead-free solder substantially containing no Pb. Aa an example of the lead-free solder, for example, only tin (Sn), tin-bismuth (Sn—Bi), or tin-copper-silver (Sn—Cu—Ag), tin-copper (Sn—Cu), and the like are given. Here, the lead-free solder means solder in which a content of lead (Pb) is 0.1 wt % or less, and the content is defined by Restriction of Hazardous Substances (RoHS) directive standards.

In addition, the plurality of solder balls SB shown by FIG. 2 are arranged in a matrix (array). Further, although illustration is omitted in FIG. 2, the plurality of lands 2LD (see FIG. 3) to which the plurality of solder balls SB are joined are also arranged in the matrix. In this way, the semiconductor device arranging the plurality of external terminals (solder balls SB, lands 2LD) in the matrix on an implementation surface side of the wiring substate SUB1 is called an area-array type semiconductor device. The area-array type semiconductor device can effectively use, as an external arrangement space of the terminal, the implementation surface (lower surface 2b) side of the wiring substrate SUB1, so that even if the number of external terminals is increased, the point is preferable that an increase in an implementation area of the semiconductor device can be suppressed. Namely, with the sophisticated functions and high integration, the semiconductor device in which the number of external terminals increases can be implemented at space saving.

The semiconductor device PKG1 has the semiconductor chip CHP1 mounted on the wiring substrate SUB1. As shown in FIG. 3, each semiconductor chip CHP1 includes an upper surface (principal surface, upper surface) 3t on which a plurality of protrusion electrodes 3BP are arranged, and a back surface (principal surface, lower surface) 3b opposite to the upper surface 3t.

The semiconductor device CHP1 has a quadrangular external shape whose planer area is smaller than that of the wiring substrate SUB1 in the plan view as shown in FIG. 1. In the example shown by FIG. 1, the semiconductor chip CHP1 is mounted on a center portion of the upper surface 2t in the wiring substrate SUB1. In addition, each of four sides of the semiconductor chip CHP1 extends along each of four sides (side 2s1, side 2s2, side 2s3, side 2s4) of the upper surface 2t of the wiring substrate SUB1.

As shown in FIG. 3, a plurality of electrodes (pads, electrode pads, bonding pads) 3PD are formed on an upper surface 3t side of the semiconductor chip CHP1. The upper surface 3t is the outermost surface of the semiconductor chip CHP1. An upper surface of a not-shown passivation film and an upper surface of the electrode 3PD exposed from the passivation film is included in the upper surface 3t. Since the plurality of protrusion electrodes 3BP is formed on the electrode 3PD, it can be expressed that the plurality of protrusion electrodes 3BP are formed on the upper surface 3t.

In the example shown by FIG. 3, the semiconductor chip CHP1 is mounted on the wiring substrate SUB1 in a state in which the upper surface 3t is opposite to the p surface 2t of the wiring substrate SUB1. Such a mounting method is called a face down implementation method or a flip chip connection method.

Although omitted in the figure, a plurality of semiconductor elements (circuit elements) are formed on the principal surface (specifically, a semiconductor element formation region provided on an element formation surface of the semiconductor device that is a basic material of the semiconductor chip CHP1) of the semiconductor device CHP1. The plurality of electrodes 3PD are respectively electrically connected to those plural semiconductor elements via wirings (omitted in the figure) which are formed on a wiring layer arranged inside the semiconductor chip CHP1 (specifically, between the upper surface 3t and the not-shown semiconductor element formation region).

The semiconductor chip CHP1 (specifically, a semiconductor substrate of the semiconductor chip CHP1) is made of, for example, silicon (Si). In addition, the semiconductor substrate of the semiconductor chip CHP1 and an insulation film (not-shown passivation film) covering the wirings are formed on the upper surface 3t, and a part of each of the plurality of electrodes 3PD is exposed from the passivation film in an opening formed in this passivation film. Further, each of the plurality of electrodes 3PD is made of metal, for example, aluminum (Al) in the present embodiment.

In addition, as shown in FIG. 3, the protrusion electrode 3BP is connected to each of the plurality of electrodes 3PD, and the plurality of electrodes 3PD of the semiconductor chip CHP1 and the plurality of pads 2PD of the wiring substrate are respectively electrically connected to each other via the plurality of protrusion electrodes 3PD. The protrusion electrode (bump electrode) 3BP is a metal member (conductive member) formed so as to protrude from the upper surface 3t of the semiconductor chip CHP1. In the present embodiment, the protrusion electrode 3BP has a structure in which a columnar electrode (so-called copper pillar electrode) made of, for example, copper is formed and a solder material is laminated at a tip of the columnar electrode. As the solder material laminated at the tip of the columnar electrode, a lead-containing solder material and lead-free solder can be used similarly to the above solder ball SB.

When the semiconductor chip CHP1 is mounted on the wiring substrate SUB1, a jointing material (for example, foundation metal film and solder paste) having good jointing properties to the solder is previously formed on the plurality of pads 2PD. By performing a heating processing (reflow processing) in a state of contacting a solder material at the tip of the columnar electrode and the jointing material on the pad 2PD with each other, the solder is integrated and the protrusion electrode 3BP is formed. In addition, as a modification example with respect to the present embodiment, the columnar electrode made of nickel (Ni) or a so-called solder bump in which a micro soler ball is formed on the electrode 3PD via the foundation metal film may be used as the protrusion electrode 3BP.

In addition, an underfill resin (insulation resin) UF is arranged between the semiconductor chip CHP1 and the wiring substrate SUB1 as shown in FIG. 3. The underfill resin UF is arranged so as to fill a space between the upper surface 3t of the semiconductor chip CHP1 and the upper surface 2t of the wiring substrate SUB1. Each of the plurality of protrusion electrodes 3BP is sealed by the underfill resin UF. Further, the underfill resin UF is made of an insulation (non-conductive) material (for example, resin material), and is arranged so as to seal an electrical connection portion (a jointing portion of the plurality of protrusion electrodes 3BP) of the semiconductor chip CHP1 and the wiring substrate SUB1. In this way, by covering the electrical connection portion of the semiconductor chip CHP1 and the plurality of pads 2PD with the underfill resin UF, a stress occurring at the electrical connection portion of the semiconductor chip CHP1 and the wiring substrate SUB1 can be relieved. Furthermore, a stress occurring at the joining portion of the plurality of electrodes 3PD and the plurality of protrusion electrodes 3BP in the semiconductor chip CHP1 can also be relieved. Moreover, the principal surface on which the semiconductor element (circuit element) of the semiconductor chip CHP1 is formed can also be protected.

As shown in FIG. 3, the stiffener ring 4 is jointed and fixed onto the wiring substrate SUB1 via a plurality of adhesive layers BND including an adhesive layer BND3 and an adhesive layer BND4. As shown in FIG. 1, the stiffener ring 4 is an annular member arranged so as to continuously surround a periphery of the semiconductor chip CHP1 in a plan view. The stiffener ring 4 is made of metal such as copper (Cu). Note that in using the copper stiffener ring 4, a metallic film such as nickel may be formed on a surface (for example, an upper surface, a lower surface, and an internal surface) of the stiffener ring 4 from the viewpoint of preventing oxidation of the surface.

One purpose for mounting the stiffener ring 4 on the wiring substrate SUB1 is a point of suppressing the warpage deformation of the wiring substrate SUB1. The warpage deformation of the wiring substrate SUB1 is caused by a stress generated when a temperature change occurs at the wiring substrate SUB1. In the plan view, the greatest stress is applied to a circumferential portion of the upper surface 2t of the wiring substrate SUB1. Accordingly, the stiffener ring 4 is arranged along the circumferential portion of the upper surface 2t.

By the way, in a BGA type semiconductor device, there is a cover member called a lid as a member arranged so as to cover the semiconductor chip. Since arranged on the wiring substrate so as to cover the semiconductor chip, the lid is bonded at not only the wiring substrate but also the semiconductor chip. Accordingly, in addition to a strength of an adhesive layer for bonding the lid and the wiring substrate, a strength at which the lid is fixed to the wiring substrate via the semiconductor chip contributes to an adhesive strength between the lid and the wiring substrate. Meanwhile, since the stiffener ring 4 of the present embodiment is the annular member, the stiffener ring 4 and the semiconductor chip CHP1 are separated from each other. That is, the stiffener ring 4 is arranged on the wiring substrate SUV1 so as not to cover the semiconductor chip CHP1. In this case, a fixing strength between the semiconductor chip CHP1 and the wiring substrate SUB1 does not contribute to the adhesive strength between the stiffener ring 4 and the wiring substrate SUB1. In order to suppress the warpage deformation of the wiring substrate SUB1 by the stiffener ring 4, the stiffener ring 4 needs to be firmly fixed to the wiring substrate SUB1, so that the adhesive strength of the adhesive layer becomes an important element.

Note that since the stiffener ring 4 is the annular member, the back surface 3b of the semiconductor chip CHP1 is exposed even after mounting the stiffener ring 4 on the wiring substrate SUB1. In this case, for example, a heat-dissipation heat sink and the like having a size larger than a size of the upper surface 2t of the wiring substrate SUB1 can contact the back surface 3b of the semiconductor chip CHP1.

As a method of improving the adhesive strength between the stiffener ring 4 and the wiring substrate SUB1, a method of arranging the adhesive layer all around the stiffener ring 4 is conceivable. However, it may be preferable in some cases that the adhesive layer is not arranged between the stiffener ring 4 and the wiring substrate SUB1.

For example, from the viewpoint of reducing a usage amount of adhesive layers and suppressing manufacturing costs of the semiconductor device PKG1, there is preferably a space, in which no adhesive layer is arranged, between the stiffener ring 4 and the wiring substrate SUB1.

Or, in a manufacturing step of the semiconductor device PKG1, a cleaning step may be performed to remove a flux component after forming the solder ball. In this case, washing liquid comes around not only the lower surface 2b (see FIG. 3) of the wiring substrate SUB1 but also the upper surface 2t (see FIG. 3). From the viewpoint of preventing the washing liquid coming around the upper surface 2t from being accumulated, there is preferably the space, in which no adhesive layer is arranged, between the stiffener ring 4 and the wiring substrate SUB1. This is because by discharging the washing liquid via the space in which no adhesive layer is arranged, the accumulation of the washing liquid can be suppressed.

Based on the above, the present inventor has considered a fixing method on the premise that the stiffener ring 4 and the wiring substrate SUB1 are fixed onto the wiring substrate SUB1 via the plurality of adhesive layers and that the plurality of adhesive layers are separated from each other. Details thereof will be explained below.

### <Layout of Parts Mounted on Upper Surface of Wiring Substrate>

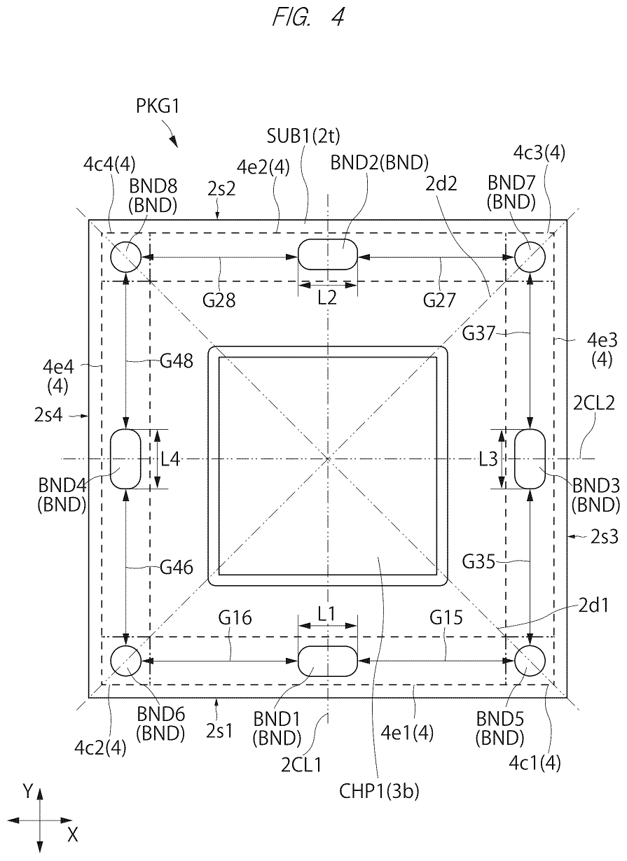

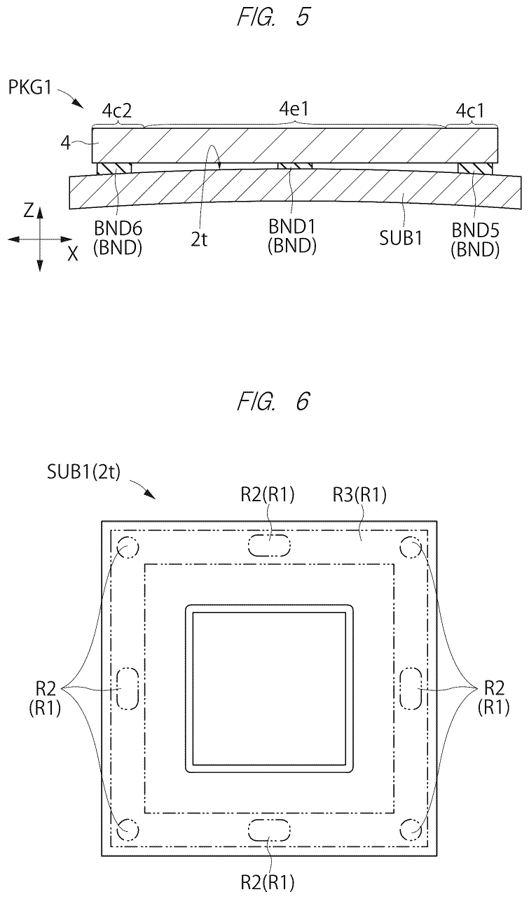

Next, a layout of a plurality of parts mounted on the upper surface 2t of the wiring substrate SUB1 will be explained. FIG. 4 is a perspective plan view showing the adhesive layer between the stiffener ring and the wiring substrate by passing through the stiffener ring of FIG. 1. FIG. 4 shows an outline of the stiffener ring 4 shown in FIG. 1 by dotted lines. FIG. 5 is an explanatory diagram schematically showing a relationship between a direction in which the wiring substrate is transformed and the stiffener ring mounted on the wiring substrate. Note that FIG. 5 is a cross-sectional view taken along an extension direction of an extension portion 4e1 shown by FIG. 4. FIG. 6 is a plan view showing a state in which the stiffener ring of FIG. 1 and the adhesive layer are removed. Note that FIG. 6 shows, by dash-double-dot lines, an outline in which the adhesive layer BND shown in FIG. 4 is arranged, and an outlie of a region in which the stiffener ring 4 is arranged.

As shown in FIG. 1, the upper surface 2t of the wiring substrate SUB1 includes a side 2s1, a side 2s2 opposite to the side 2s1, a side 2s3 intersecting with the side 2s1 and the side 2s2, and a side 2s4 opposite to the side 2s3. In addition, the upper surface 2t includes a corner 2c1 that is an intersection of the side 2s1 and the side 2s3, a corner 2c2 that is an intersection of the side 2s1 and the side 2s4, a corner 2c3 that is an intersection of the side 2s2 and the side 2s3, and a corner 2c4 that is an intersection of the side 2s2 and the side 2s4.

In addition, although being a virtual line which is not a visible line, the upper surface 2t is a quadrangular shape, so that two diagonal lines can be drawn. That is, a diagonal line 2d1 connecting the intersection (corner 2c1) of the side 2s1 and the side 2s3 and the intersection (corner 2c4) of the side 2s2 and the side 2s4 can be drawn on the upper surface 2t. Further, a diagonal line 2d2 connecting the intersection (corner 2c2) of the side 2s1 and the side 2s4, and the intersection (corner 2c3) of the side 2s2 and the side 2s3 can be drawn in the upper surface 2t. In the example shown by FIG. 1, the side 2s1 and the side 2s2 are sides extending along the X direction, and the side 2s3 and the side 2s4 are sides extending along the Y direction.

In the plan view, the stiffener ring 4 includes an extension portion 4e1 extending along the side 2s1, an extension portion 4e2 extending along the side 2s2, an extension portion 4e3 extending along the side 2s3, and an extension portion 4e4 extending along the side 2s4. In addition, the stiffener ring 4 includes a corner portion 4cl connected by the extension portion 4e1 and the extension portion 4e3, a corner portion 4c2 connected by the extension portion 4e1 and the extension portion 4e4, a corner portion 4c3 connected by the extension portion 4e2 and the extension portion 4e3, and a corner portion 4c4 connected by the extension portion 4e2 and the extension portion 4e4.

When the diagonal line 2d1 shown by FIG. 1 is drawn, the corner portion 4c1 and the corner portion 4c4 overlap with the diagonal line 2d1 in the plan view. In addition, when the diagonal line 2d2 is drawn, the corner portion 4c2 and the corner portion 4c3 overlap with the diagonal line 2d2.

As shown in FIG. 3, the stiffener ring 4 is fixes to the upper surface 2t of the wiring substrate SUB1 via the plurality of adhesive layers (the adhesive layer BND3 and the adhesive layer BND4 is illustrated in FIG. 3) arranged between the stiffener ring 4 and the upper surface 2t of the wiring substrate SUB1 so as to be separated from each other. In addition, although being the virtual line that is not the visible line actually, the upper surface 2t of the wiring substrate SUB1 is a quadrangular shape, so that two center lines can be drawn as shown in FIG. 4. That is, a center line 2CL1 connecting a center of the side 2s1 and a center of the side 2s2 can be drawn on the upper surface 2t. Further, a center line 2CL2 connecting a center of the side 2s3 and a center of the side 2s4 can be drawn on the upper surface 2t.

As shown in FIG. 4, in the case of the present embodiment, the plurality of adhesive layers BND includes an adhesive layer BND1 arranged at a portion overlapping with the extension portion 4e1 (see FIG. 1) and arranged at a portion overlapping with the center line 2CL1, an adhesive layer BND2 arranged at a portion overlapping with the extension portion 4e2 (see FIG. 1) and arranged at a portion overlapping with the center line 2CL1, an adhesive layer BosiND3 arranged at a portion overlapping with the extension portion 4e3 (see FIG. 1) and arranged at a portion overlapping with the center line 2CL2, and an adhesive layer p4 arranged at a portion overlapping with the extension portion 4e4 (see FIG. 1) and arranged at a portion overlapping with the center line 2CL2.

In addition, the plurality of adhesive layers BND include an adhesive layer BND5 arranged at a portion overlapping with the corner portion 4c1 and arranged at a portion overlapping with the diagonal line 2d1, an adhesive layer BND6 arranged at a portion overlapping with the corner portion 4c2 and arranged at a portion overlapping with the diagonal line 2d2, an adhesive layer BND7 arranged at a portion overlapping with the corner portion 4c3 and arranged at a portion overlapping with the diagonal line 2d2, and an adhesive layer BND8 arranged at a portion overlapping with the corner portion 4c4 and arranged at a portion overlapping with the diagonal line 2d1.

According to the consideration by the inventor of the present application, from the viewpoint of suppressing the warpage deformation of the wiring substrate SUB1, the adhesion layers BND are preferably arranged at at least eight portions as shown in FIG. 4.

As schematically shown in FIG. 5, when the wiring substrate SUB1 warps and deforms, the center of the upper surface 2t becomes convex. In other words, the wiring substrate SUB1 deforms that of a so height the circumferential portion becomes lower than the height of the center portion of the upper surface 2t.

When the stiffener ring 4 does not deform by having sufficiently high rigidity, a force for suppressing the warpage deformation of the wiring substrate SUB1 is applied via the adhesive layer BND bonded to the stiffener ring 4 and the wiring substrate SUB1. From the viewpoint of effectively suppressing the warpage deformation, the adhesive layers BND are preferably arranged at a portion with the least deformation amount and at a portion with the largest deformation amount, respectively.

According to the present embodiment, the adhesive layers BND are arranged at the eight portions as shown by FIG. 4, so that when the wiring substrate SUB1 warps and deforms, the adhesive layers are bonded at the portion with the least deformation amount and the portion with the largest deformation amount, respectively.

As a result of experimental confirmation of suppression effects of the warpage deformation of the wiring substrate SUB1 through the embodiment shown in FIG. 4 by the inventor of the present application, when the adhesive layers BND are arranged at the eight portions shown in FIG. 4, it has found that the same effects as those when the adhesive layers BND are arranged all around the stiffener ring 4 are obtained.

Meanwhile, focusing on the usage amount, a total value of volumes of the eight adhesive layers BND of the adhesive layer BND1 to the adhesive layer BND8 is less than half in comparison with a volume when the adhesive layer BND is arranged all around the stiffener ring 4.

Therefore, according to the present embodiment, it is found that such an adhesive strength as to be capable of suppressing the warpage deformation of the wiring substrate SUB1 is ensured and, simultaneously, the usage amount of the adhesive layers BND can be reduced.

Note that each of the adhesive layer BND5, the adhesive layer BND6, the adhesive layer BND7, and the adhesive layer BND8 that are shown by FIG. 4 overlaps with the diagonal line 2d1 or the diagonal line 2d2 as described above. Considering the warpage deformation along each side of the upper surface 2t formed in a quadrangular shape, since the adhesive layer BND is arranged at a portion overlapping with the diagonal line 2d1 or the diagonal line 2d2, an amount of the adhesive layers BND can be made little.

For example, the adhesive layer BND5 shown by FIG. 4 has a function as the adhesive layer BND for suppressing the warpage deformation along the extension direction of the extension portion 4e1 and a function as the adhesive layer BND for suppressing the warpage deformation along the extension direction of the extension portion 4e3. In this case, the usage amount of the adhesive layers BND can be reduced in comparison with a case in which the adhesive layers BND are arranged at three portions along each of the extension direction of the extension portion 4e1 and the extension direction of the extension portion 4e3.

In a case of an example shown by FIG. 4, from the viewpoint of the usage amount of the adhesive layers BND being little, the following expressions can be made. That is, the adhesive layer BND1 extends in the X direction. A length L1 of the adhesive layer BND1 in the X direction is shorter than a separation distance G15 between the adhesive layer BND1 and the adhesive layer BND5 in the X direction and a separation distance G16 between the adhesive layer BND1 and the adhesive layer BND6 in the X direction.

In addition, a length L2 of the adhesive layer BND2 in the X direction is shorter than a separation distance G27 between the adhesive layer BND2 and the adhesive layer BND7 in the X direction and a separation distance G28 between the adhesive layer BND2 and the adhesive layer BND8 in the X direction. Further, a length L3 of the adhesive layer BND3 in the Y direction orthogonal to the X direction is shorter than a separation distance G35 between the adhesive layer BND3 and the adhesive layer BND5 in the Y direction and a separation distance G37 between the adhesive layer BND3 and the adhesive layer BND7 in the Y direction. Moreover, a length L4 of the adhesive layer BND2 in the Y direction is shorter than a separation distance G46 between the adhesive layer BND4 and the adhesive layer BND6 in the Y direction and a separation distance G48 between the adhesive layer BND4 and the adhesive layer BND8 in the Y direction.

In addition, in the case of the example of the present embodiment, from the viewpoint of the usage amount of the adhesive layers BND being little, the following expression can be made. That is, the adhesive layer BND1 has a region R1 in which the upper surface 2t of the wiring substrate SUB1 overlaps with the stiffener ring 4 in the plan view. The region R1 has a region R2 in which the wiring substrate SUB1 and the stiffener ring 4 (see FIG. 1) are opposite to each other via the plurality of adhesive layers BND (see FIG. 4), and a region R3 in which the wiring substrate SUB1 and the stiffener ring 4 (see FIG. 1) are opposite to each other without passing through the plurality of adhesive layers BND. An area (specifically, a total value of the areas of the regions R2 at the eight portions shown by FIG. 6) of the region R2 in the region R1 is smaller than an area of the region R3. Note that the area of the region R3 can be defined as a difference between the area of the entire region R1 and the total value of the plurality of regions R2.

In the case of the present embodiment, since the adhesive layers BND are arranged at the eight portions particularly important from the viewpoint of suppressing the warpage deformation of the wiring substrate SUB1, the usage amount of the adhesive layers BND can be reduced as mentioned above. That is, according to the present embodiment, the usage amount of the adhesive layers BND is reduced, and the manufacturing costs of the semiconductor device PKG1 can be suppressed. Or, in the manufacturing method of the above semiconductor device, from the viewpoint of preventing the accumulation of the washing liquid for removing the flux component, the followings are mentioned. That is, according to the present embodiment, the washing liquid is exhausted via the space in which the adhesive layer BND is not arranged (a space above the region R3 shown by FIG. 6). Consequently, the accumulation of the washing liquid can be suppressed.

### Modification Example of Layout of Adhesive Layer

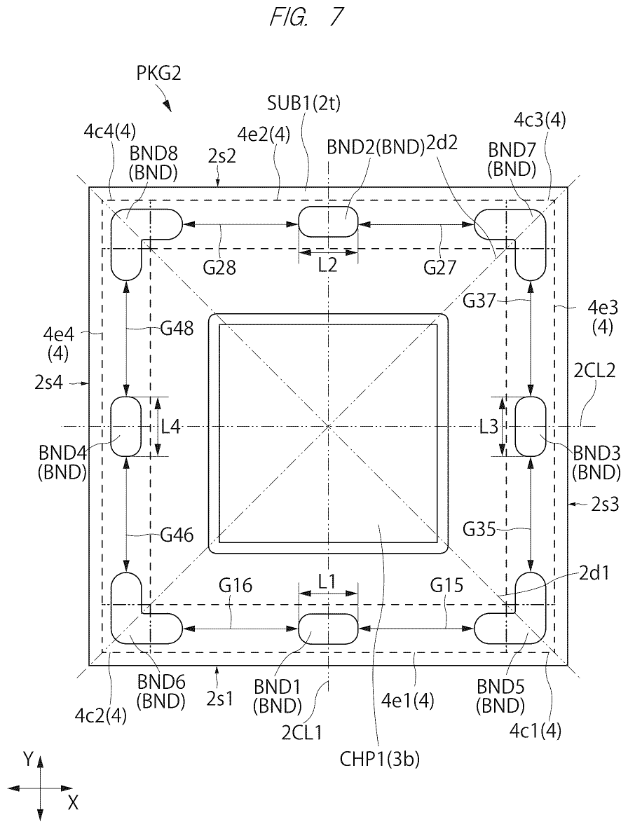

Next, a modification example of the layout of the adhesive layers BND shown by FIG. 4 will be explained. FIG. 7 is a plan view showing a modification example with respect to FIG. 4.

A semiconductor device PKG2 shown in FIG. 7 is different from the semiconductor device PKG1 shown by FIG. 4 in a shape of the adhesive layer BND, which are arranged at the portion overlapping with a corner portion of the stiffener ring 4, among the plurality of adhesive layers BND. Specifically, among the plurality of adhesive layers BND, each of the adhesive layer BND5 arranged at a portion overlapping with a corner portion 4c1 of the stiffener ring 4, the adhesive layer BND6 arranged at a portion overlapping with a corner portion 4c2 of the stiffener ring 4, the adhesive layer BND7 arranged at a portion overlapping with a corner portion 4c3 of the stiffener ring 4, and the adhesive layer BND8 arranged at a portion overlapping with a corner portion 4c4 of the stiffener ring 4 is formed in an L shape.

The adhesive layer BND5 has a portion arranged at the portion overlapping with the corner portion 4c1 of the stiffener ring 4, a portion arranged at the portion overlapping with the extension portion 4e1 continuous to the corner portion 4cl, and a portion arranged at the portion overlapping with the extension portion 4e3 continuous to the corner portion 4cl.

Similarly, the adhesive layer BND6 has a portion arranged at the portion overlapping with the corner portion 4c2 of the stiffener ring 4, a portion arranged at the portion overlapping with the extension portion 4e1 continuous to the corner portion 4c2, and a portion arranged at the portion overlapping with the extension portion 4e3 continuous to the corner portion 4c2.

Similarly, the adhesive layer BND7 has a portion arranged at the portion overlapping with the corner portion 4c3 of the stiffener ring 4, a portion arranged at the portion overlapping with the extension portion 4e2 continuous to the corner portion 4c3, and a portion arranged at the portion overlapping with the extension portion 4e3 continuous to the corner portion 4c3.

Similarly, the adhesive layer BND8 has a portion arranged at the portion overlapping with the corner portion 4c4 of the stiffener ring 4, a portion arranged at the portion overlapping with the extension portion 4e2 continuous to the corner portion 4c4, and a portion arranged at the portion overlapping with the extension portion 4e4 continuous to the corner portion 4c4.

In a case of the modification example shown by FIG. 7, the plurality of adhesive layers BND arranged at the portions overlapping with the corner portions of the stiffener ring 4 can increase the areas bonded to the wiring substrate SUB1. In the example shown by FIG. 7, a contact area that contacts with each of the adhesive layer BND5, the adhesive layer BND6, the adhesive layer BND7, and the adhesive layer BND8 is larger than a contact area of the adhesive layer that has the largest contact area with the wiring substrate SUB1 among the adhesive layer BND1, the adhesive layer BND2, the adhesive layer BND3, and the adhesive layer BND4. In the example shown by FIG. 7, the contact areas whose respective adhesive layer BND5, adhesive layer BND6, adhesive layer BND7, and adhesive layer BND8 contact with the wiring substrate SUB1 are equal to each other.

As explained by using FIG. 5, the wiring substrate SUB1 deforms so that a height of the circumferential portion is larger than a height of the center portion of the upper surface 2t. Consequently, in the circumferential portion of the wiring substrate SUB1, an external force acts in a direction separating from distances of the stiffener ring 4 and the wiring substrate SUB1. Each of the adhesive layer BND5, the adhesive layer BND6, the adhesive layer BND7, and the adhesive layer BND8 is provided to resist the force acting in the direction separating from the distances of the stiffener ring 4 and the wiring substrate By increasing an adhesive force of each of the adhesive layer BND5, the adhesive layer BND6, the adhesive layer BND7, and the adhesive layer BND8, suppression effects of the warpage deformation become greater.

In a case of the present modification example, by increasing the area of each of the adhesive layer BND5, the adhesive layer BND6, the adhesive layer BND7, and the adhesive layer BND8 that is bonded to the wiring substrate SUB1, those adhesive forces are strengthened.

Note that from the viewpoint of suppressing the accumulation of the above washing liquid, each shape of the adhesive layer BND5, the adhesive layer BND6, the adhesive layer BND7, and the adhesive layer BND8 shown by FIG. 7 easily causes the accumulation of the washing liquid in comparison with each shape of the adhesive layer BND5, the adhesive layer BND6, the adhesive layer BND7, and the adhesive layer BND8 shown by FIG. 4.

Accordingly, from the viewpoint of suppressing the accumulation of the washing liquid, as shown by FIG. 4, a planar shape of each of the adhesive layer BND5, the adhesive layer BND6, the adhesive layer BND7, and the adhesive layer BND8 is preferably a circular or an oval.

The semiconductor device PKG2 shown by FIG. 7 is same as the semiconductor device PKG1 explained by using FIG. 1 to FIG. 6 except different points mentioned above. Accordingly, duplicate explanation thereof will be omitted.

### Modification Example of Shape of Stiffener Ring

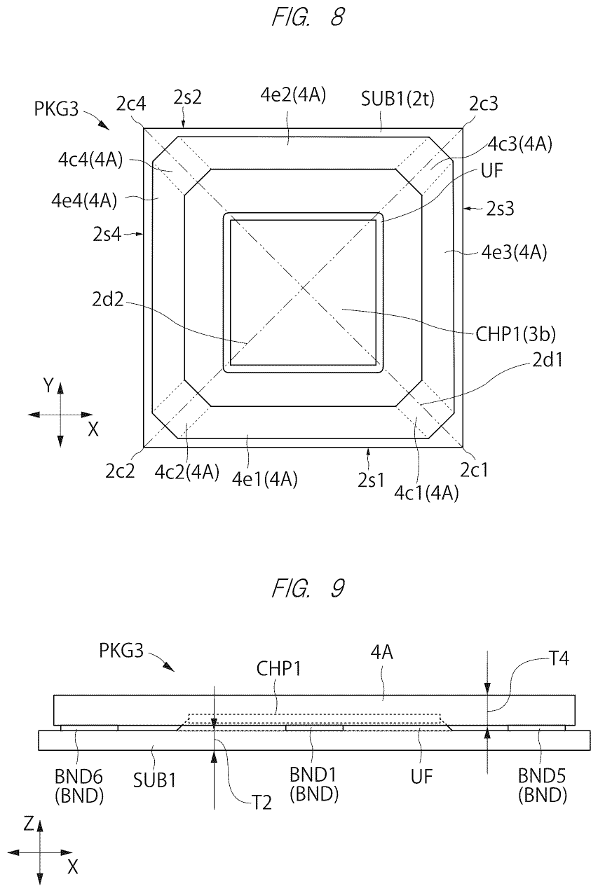

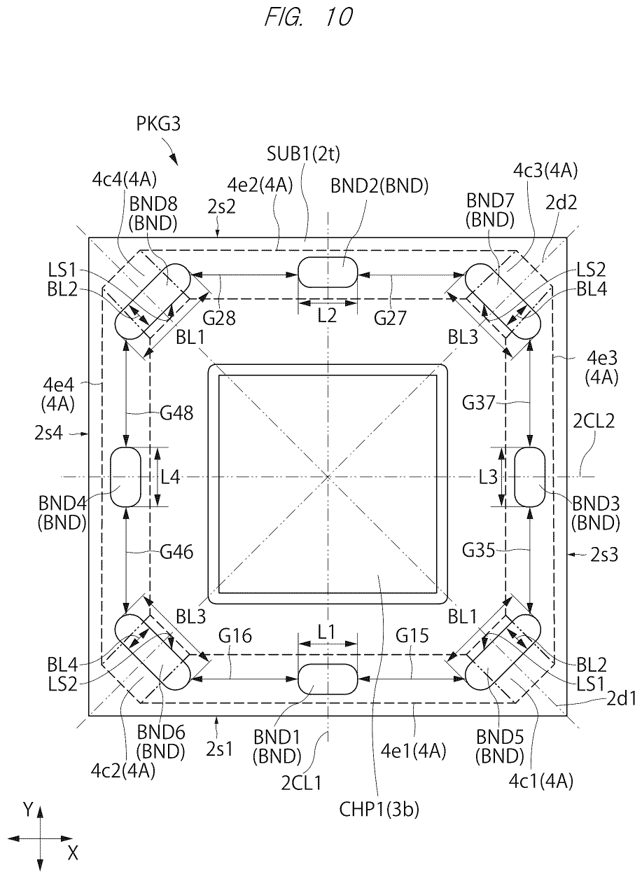

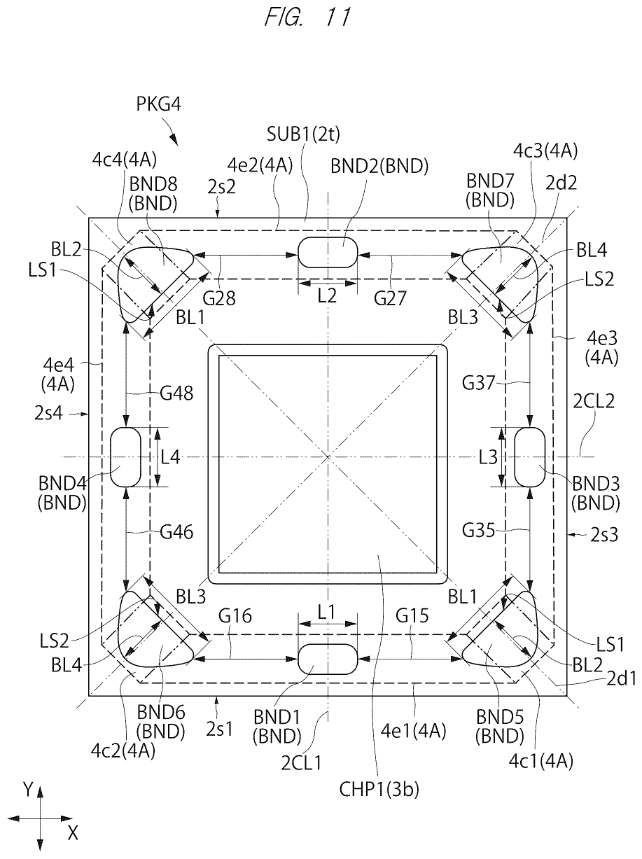

Next, a modification example with respect to the semiconductor device explained by using FIG. 1 to FIG. 6 will be explained. Firstly, a modification example of the stiffener ring shown by FIG. 1 will be explained. FIG. 8 is a plan view showing a semiconductor device that is a modification example with respect to FIG. 1. FIG. 9 is an explanatory diagram of the semiconductor device of FIG. 8. FIG. 10 is a perspective plan view showing an adhesive layer between the stiffener ring and the wiring substrate by passing through the stiffener ring shown by FIG. 8.

A semiconductor device PKG3 shown by FIG. 8 to FIG. 10 is different from the semiconductor device PKG1 explained by using FIG. 1 to FIG. 6 in the followings.

As shown in FIG. 9, a stiffener ring 4A that the semiconductor device PKG3 has is different from the stiffener ring 4 of the semiconductor device PKG1 shown by FIG. 3 in that its thickness is larger. In an example shown by FIG. 9, a thickness T4 of the stiffener ring 4A is larger than a thickness T2 of the wiring substrate SUB1. By increasing the thickness T4 of the stiffener ring 4A, rigidity of the stiffener ring 4A can be improved. The increase in the rigidity of the stiffener ring 4A is preferable in that the stiffener ring 4A itself does not easily deform even if a strong exterior force is applied to the stiffener ring 4A.

However, even when the rigidity of the stiffener ring 4A is improved, the wiring substrate SB1 cannot be prevented from deforming unless the stiffener ring 4A and the wiring substrate SUB1 are firmly fixed to each other. Accordingly, like the stiffener ring 4A of the present modification example, even when the thick stiffener ring 4A is used, it is required that the plurality of adhesive layers BND are arranged at proper portions and the adhesive strength between the stiffener ring 4A and the wiring substrate SUB1 is ensured, as already explained, in order to prevent the wiring substrate SUB1 from deforming.

Note that an embodiment in which the thickness of the stiffener ring 4A is larger than that of the wiring substrate SUB1 is not limited to the present modification example. For example, as a modification example with respect to the stiffener ring 4 shown by FIG. 3, the thickness of the stiffener ring 4 may be larger than the thickness of the wiring substrate SUB1 including the core insulation layer 2CR.

In addition, as shown in FIG. 8, in the semiconductor device PKG3, a planar shape of the stiffener ring 4A is different from that of the stiffener ring 4 shown by FIG. 1. Specifically, the stiffener ring 4A is different from the stiffener ring 4 shown by FIG. 1 in each planar shape of the corner portion 4cl, the corner portion 4c2, the corner portion 4c3, and the corner portion 4c4.

Each of the corner portion 4cl, the corner portion 4c2, the corner portion 4c3, and the corner portion 4c4 that the stiffener ring 4A has extends in a direction intersecting with each of the X direction and the Y direction. An angle formed by each extension direction of the corner portion 4cl, the corner portion 4c2, the corner portion 4c3, and the corner portion 4c4 and the X direction is, for example, 45 degrees. Similarly, an angle formed by each extension direction of the corner portion 4cl, the corner portion 4c2, the corner portion 4c3, and the corner portion 4c4 and the Y direction is, for example, 45 degrees.

Note that each of the corner portion 4cl, the corner portion 4c2, the corner portion 4c3, and the corner portion 4c4 extends in the direction intersecting with each of the X direction and the Y direction, but an extension distance of each corner portion is not long. For example, each extension distance of the corner portion 4cl, the corner portion 4c2, the corner portion 4c3, and the corner portion 4c4 is shorter than each extension distance of the extension portion 4cl, the extension portion 4c2, the extension portion 4c3, and the extension portion 4c4.

The stiffener ring 4A formed so that each corner portion is tilted with respect to each of the X direction and the Y direction as shown by FIG. 8 may be called a taper shape or a chamfered shape. In this case, each corner portion may be called a taper portion or a chamfered portion. In a case of the present modification example, as shown by FIG. 8, on the upper surface 2t of the wiring substrate SUB1, an exposure area of the upper surface 2t becomes larger than that of the example shown by FIG. 1 on the vicinity of each of four corners 2cl, 2c2, 2c3, and 2c4. An identification mark used in a manufacturing process and the like may be arranged around the corners of the upper surface 2t. Like the present modification example, the increase in the exposure area from the stiffener ring 4 around the corners of the upper surface 2t makes it possible to improve visibility of the mark.

In addition, in the case of the present modification example, by the four corner portions of the stiffener ring 4A being formed in a taper shape, the planer shapes of the adhesive layer BND5, the adhesive layer BND6, the adhesive layer BND7, and the adhesive layer BND8 are different from those of the embodiment shown by FIG. 4.

In the case of the semiconductor device PKG3 shown by FIG. 10. in each of the adhesive layer BND5 and the adhesive layer BND8, a length BL1 in a direction intersecting with the diagonal line 2d1 is longer than a length BL2 in a direction extending along the diagonal line 2d1 in the plan view. In addition, in each of the adhesive layer BND6 and the adhesive layer BND7, a length BL3 in a direction intersecting with the diagonal line 2d2 is longer than a length BL4 in a direction extending along the diagonal line 2d2. Lengthening the length BL1 and the length BL3 makes it possible to increase the adhesive areas between the adhesive layers BND and the wiring substrate SUB1. Further, in the case of the present modification example, even when the length BL1 and the length BL3 are lengthened, each of the plurality of adhesive layers BND can be prevented from protruding outside from the portion overlapping with the stiffener ring 4 in the plan view.

In addition, a layout of the adhesive layers BND in the semiconductor device PKG3 shown by FIG. 10 can be expressed as follows. That is, each of the adhesive layer BND5 and the adhesive layer BND8 is opposite to the semiconductor device CHP1 in the plan view, and has a long side LS1 extending in a direction intersecting with the diagonal line 2d1. Each of the adhesive layer BND6 and the adhesive layer BND7 is opposite to the semiconductor device CHP1 in the plan view, and has a long side LS2 extending in a direction intersecting with the diagonal line 2d2. In this case, the modification example has a structure, in which the above washing liquid is difficult to accumulate, in comparison with the shapes of the adhesive layer BND5, the adhesive layer BND6, the adhesive layer BND7, and the adhesive layer BND8 shown by FIG. 7. Accordingly, in comparison with the semiconductor device PKG2 explained by using FIG. 7, it is said that the semiconductor device PKG3 of the present modification example has a structure in which the accumulation of the washing liquid can be prevented.

In addition, the semiconductor device PKG3 shown by FIG. 10 is the same as the semiconductor device PKG2 explained by using FIG. 7 in that the plurality of adhesive layers BND arranged at the portions overlapping with the corner portions of the stiffener ring 4A increase the areas bonded to the wiring substrate SUB1.

That is, the contact area at which each of the adhesive layer BND5, the adhesive layer BND6, the adhesive layer BND7, and the adhesive layer BND8 contacts with the wiring substrate SUB1 is larger than the contact area of the adhesive layer which has the largest contact area with the wiring substrate SUB1 among the adhesive layer BND1, the adhesive layer BND2, the adhesive layer BND3, and the adhesive layer BND4. In the example shown by FIG. 10, the contact areas at which the respective adhesive layer BND5, adhesive layer BND6, adhesive layer BND7, and adhesive layer BND8 contact with the wiring substrate SUB1 are equal to one another.

FIG. 11 is a perspective plan view showing a modification example with respect to FIG. 10. A semiconductor device PKG4 shown by FIG. 11 is different from the semiconductor device PKG3 shown by FIG. 10 in each planar shape of the adhesive layer BND5, the adhesive layer BND6, the adhesive layer BND7, and the adhesive layer BND8, which are arranged at the four corner portions of the stiffener ring 4, among the plurality of adhesive layers BND.

Specifically, in the plan view, each of the adhesive layer BND5, the adhesive layer BND6, the adhesive layer BND7, and the adhesive layer BND8 is a triangle. Note that each corner of the triangle as shown by FIG. 11 becomes a round shape, but if it is assumed that a portion of the round shape is regarded as a corner, the round shape can be regarded as the triangle.

In a case of the semiconductor device PKG4, the contact area at which each of the adhesive layer BND5, the adhesive layer BND6, the adhesive layer BND7, and the adhesive layer BND8 contacts with the wiring substrate SUB1 is further larger than that of the semiconductor device PKG3 shown by FIG. 10. As described above, from the viewpoint of preventing the warpage deformation of the wiring substrate SUB1, it is effective to improve the adhesive strength between the stiffener ring 4A and the wiring substrate SUB1 at the corner portions of the stiffener ring 4A. Accordingly, from the viewpoint of preventing the warpage deformation of the wiring substrate SUB1, the semiconductor device PKG4 is even more preferable than the semiconductor device PKG3.

Meanwhile, from the viewpoint of reducing the amount of the adhesive layers BND, the semiconductor device PKG3 shown by FIG. 10 is preferable.

The semiconductor device PKG3 shown by FIG. 8 to FIG. 10 and the semiconductor device PKG4 shown by FIG. 11 are the same as the semiconductor device PKG1 explained by using FIG. 1 to FIG. 6 except the above difference. Accordingly, the duplicated explanation thereof will be omitted.

### Another Modification Example

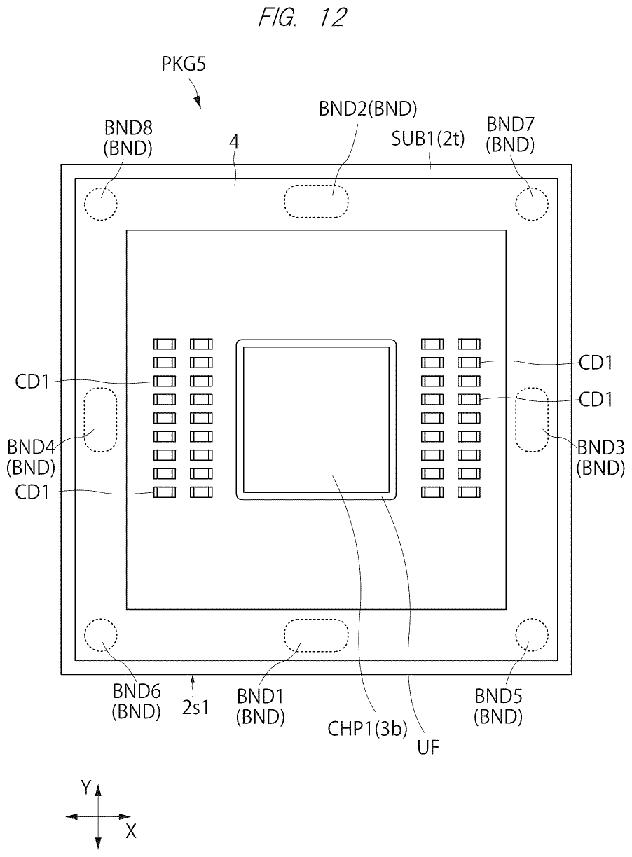

FIG. 12 is a plan view showing another modification example with respect to FIG. 1. FIG. 12 shows, by dotted lines, an outline of the plurality of adhesive layers BND arranged between the stiffener ring 4 and the wiring substrate SUB1. A semiconductor device PKG5 shown by FIG. 12 is different from the semiconductor device PKG1 shown by FIG. 1 in that the semiconductor chip CHP1 and electronic components CD1 are mounted on the upper surface 2t of the wiring substrate SUB1.

Specifically, in the plan view, the electronic components CD1 mounted on the wiring substrate SUB1 are arranged between the semiconductor chip CHP1 and the stiffener ring 4. In an example shown by FIG. 12, a plurality of electronic components CD1 are mounted between the semiconductor chip CHP1 and the stiffener ring 4.

Each of the plurality of electronic components CD1 is a surface mounted chip part, and is mounted on the wiring substrate SUB1 via the solder. Each of the plurality of electronic components CD1 has, for example, a capacitor, an inductor, a resistance. Recently, with the sophisticated functions of the semiconductor device, the plurality of electronic components CD1 may be mounted on the upper surface 2t of the wiring substrate SUB1 separately from the semiconductor chip CHP1.

In this way, when the electronic components CD1 are mounted on the wiring substrate SUB1, a size of the upper surface 2t of the wiring substrate SUB1 may increase. If the size of the upper surface 2t increases, the above warpage deformation is easily caused. This is because if a distance from a center of the upper surface 2t to its periphery becomes long, a stress applied due to thermal influence becomes strong.

A technique already explained by using FIG. 1 to FIG. 11 or a technique about a semiconductor device manufacturing method explained below is particularly effective by being applied to the semiconductor device having the wiring substrate that has the large size of the upper surface 2t and that easily causes the warpage deformation.

When the size of the upper surface 2t becomes large, a size of the stiffener ring 4 also becomes large, so that the usage amount of the adhesive layers BND also increases when the adhesive layer BND is arranged all around the stiffener ring 4. As describe above, according to the already explained embodiment, since the usage amount of the adhesive layers BND is reduced and the occurrence of the warpage deformation can be prevented, application of the semiconductor device having the large size of the upper surface 2t is particularly effective.

The semiconductor device PKG5 shown by FIG. 12 is the same as the semiconductor device PKG1 shown by FIG. 1 except the above difference. Accordingly, the duplicated explanation thereof will be omitted. However, although the semiconductor device PKG5 has been explained as the modification example with respect to the semiconductor device PKG1, it can be applied by combining the semiconductor device PKG2 explained by using FIG. 7, the semiconductor device PKG3 explained by using FIG. 8 to FIG. 10, or the semiconductor device PKG4 explained by using FIG. 11.

### <Method of Manufacturing Semiconductor Device>

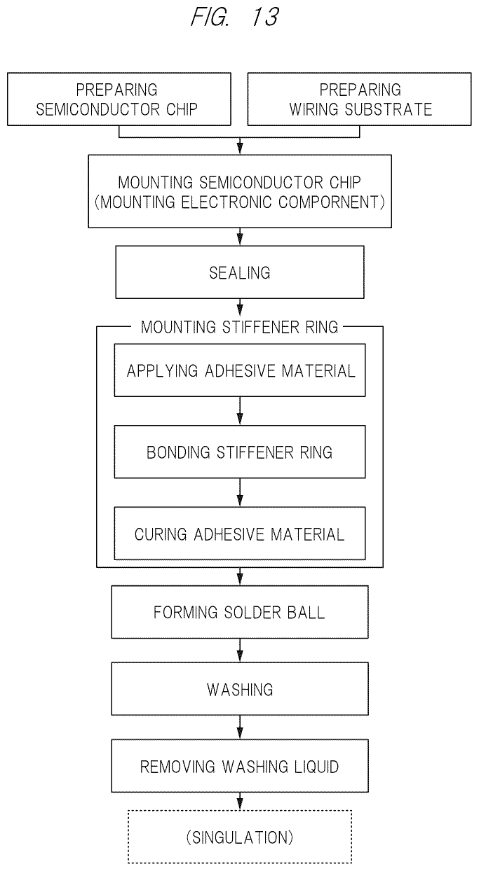

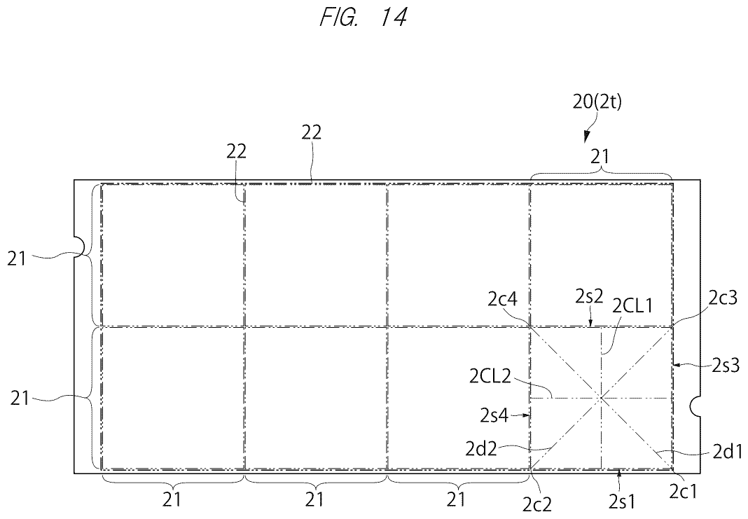

Next, a method of manufacturing a semiconductor device will be explained. Hereinafter, as a typical example, a method of manufacturing the semiconductor device PKG1 explained by using FIG. 1 to FIG. 6 will be mainly explained, and then only a different point between the above and its modification example will be explained in principle. FIG. 13 is an explanatory diagram showing a flow example of an assemble step of the semiconductor device according to the embodiment.

### <Wiring Substate Preparing Step>

As a wiring substrate preparing step shown by FIG. 13, the wiring substrate SUB1 shown by FIG. 4 is prepared. On the wiring substrate SUB prepared in this step, each member of the wiring substrate SUB1 explained by using FIG. 1 to FIG. 3 is formed. However, in a stage of this step, the wiring substrate SUB1 before the semiconductor chip CHP1 and the stiffener ring 4 are respectively mounted is prepared on the wiring substrate SUB1.

By this way, in the wiring substrate preparing step, a so-called wiring substrate 20 that is a multipiece substrate provided with a plurality of device forming portions 21 may be prepared as shown in FIG. 14. The wiring substrate 20 has the plurality of device forming portions 21, and a cutting portion 22 surrounding each periphery of the plurality of device forming portions 21. FIG. 14 is a plain view showing a modification example of the wiring substrate prepared by the wiring substrate preparing step shown in FIG. 13.

Hereinafter, the wiring substrate preparing step will be explained by using an example of preparing the substrate SUB1 shown by FIG. 1 to FIG. 6. In this step, the preparation of FIG. 14 can be applied by replacing the description of each side and each corner of the circumferential portion of the upper surface 2t by each side and each corner of a circumferential portion of the device forming portion 21. That is, each upper surface 2t of the plurality of device forming portions 21 is formed into a quadrangular shape in the plan view. Although being drawn by the virtual line that is not the visible line, each upper surface 2t of the plurality of device forming portions 21 has a side 2s1, a side 2s2 opposite to the side 2s1, a side 2s3 intersecting with the side 2s1 and the side 2s2, and a side 2s4 opposite to the side 2s3. Although being drawn by the virtual line that is not the visible line, each upper surface 2t of the plurality of device forming portions 21 has a corner 2c1 intersecting with the side 2s1 and the side 2s3, a corner 2c2 intersecting with the side 2s1 and the side 2s4, a corner 2c3 intersecting with the side 2s2 and the side 2s3, and a corner 2c4 intersecting with the side 2s2 and the side 2s4. In addition, although being drawn by the virtual line that is not the visible line, the upper surface 2t of the device forming portion 21 is a quadrilateral, so that two diagonal lines can be drawn. That is, on the upper surface 2t of the device forming portion 21, a diagonal line 2d1 connecting an intersection (corner 2cl) with the side 2s1 and the side 2s3 and an intersection (corner 2c4) with the side 2s2 and the side 2s4 can be drawn. Further, on the upper surface 2t, a diagonal line 2d2 connecting an intersection (corner 2c2) with the side 2s1 and the side 2s4 and an intersection (corner 2c3) with the side 2s2 and the side 2s3 can be drawn. In the example shown by FIG. 1, the side 2s1 and the side 2s2 are sides extending in the X direction, and the side 2s3 and the side 2s4 are sides extending in the Y direction.

Similarly, although being drawn by the virtual line that is not the visible line, the upper surface 2t of the device forming portion 21 is a quadrilateral, so that two center lines can be drawn as shown by FIG. 14. That is, on the upper surface 2t, a center line 2CL1 connecting a center of the side 2s1 and a center of the side 2s2 can be drawn. In addition, on the upper surface 2t of the device forming portion 21, a center line 2CL2 connecting a center of the side 2s3 and a center of the side 2s4 can be drawn.

### <Semiconductor Chip Preparing Step>

In addition, as a semiconductor chip preparing step shown by FIG. 13, the semiconductor chip CHP1 shown by FIG. 1, FIG. 3 and FIG. 4 is prepared. A structure of the semiconductor chip CHP1 has been already explained, so that the duplicated explanation will be omitted.

### <Semiconductor Chip Mounting Step>

Next, as a semiconductor chip preparing step shown by FIG. 13, the semiconductor chip CHP1 is mounted on the upper surface 2t of the wiring substrate USB1 shown by FIG. 3. In the semiconductor chip preparing step, the semiconductor chip CHP1 is mounted on the wiring substrate SUB1 so that its upper surface 3t opposes the upper surface 2t of the wiring substrate SUB1. Each of a plurality of electrodes 3PD of the semiconductor chip CHP1 is arranged at such a portion as to oppose each of the plurality of pads 2PD of substrate SUB1. After the wiring arranging the semiconductor chip CHP1 on the wiring substrate SUB1, each of the plurality of electrodes 3PD and the plurality of pads 2PD is electrically connected to one another via a protrusion electrode 3BP by performing a reflow processing. Such a connecting method is called a flip-chip connecting method, and the semiconductor chip mounting step of the present embodiment is called a face-down mounting method in which the upper surface 3t of the semiconductor chip CHP1 and the upper surface 2t of the wiring substrate SUB1 oppose each other.

Note that when the plurality of electronic components CD1 are mounted on the upper surface 2t of the wiring substrate SUB1 similarly to the semiconductor device PKG5 explained by using FIG. 12, an electronic component mounting step is performed as follows: the plurality of electronic components CD1 are mounted on the upper surface 2t of the wiring substrate SUB1. Each of the plurality of electronic components CD1 is electrically connected to a not-shown terminal(s) of the wiring substrate SUB1 via, for example, a solder material. In this case, the reflow processing of the semiconductor chip CHP1 and the reflow processing of the plurality of electronic components CD1 can be performed all at once.

Although being omitted in FIG. 13, a washing step for removing a residue of a flux component may be performed after the reflow processing when a solder material (omitted in figure) for mounting the protrusion electrode 3BP or the electronic component CD1 shown by FIG. 3 includes the flux component activating a solder component.

### <Sealing Step>

Next, as a sealing step shown by FIG. 13, as shown in FIG. 4, a underfill resin UF is supplied between the semiconductor chip CHP1 and the wiring substrate SUB1, and the plurality of protrusion electrodes 3BP are sealed in a state mutually insulated.

### <Stiffener Ring Mounting Step>

Next, as a stiffener ring mounting step shown by FIG. 13, as shown in FIG. 1, FIG. 3, and FIG. 4, the stiffener ring 4 is mounted on the upper surface 2t of the wiring substrate SUB1. As shown in FIG. 13, the stiffener ring mounting step includes an adhesive applying step, a stiffener ring bonding step, and an adhesive effect step.

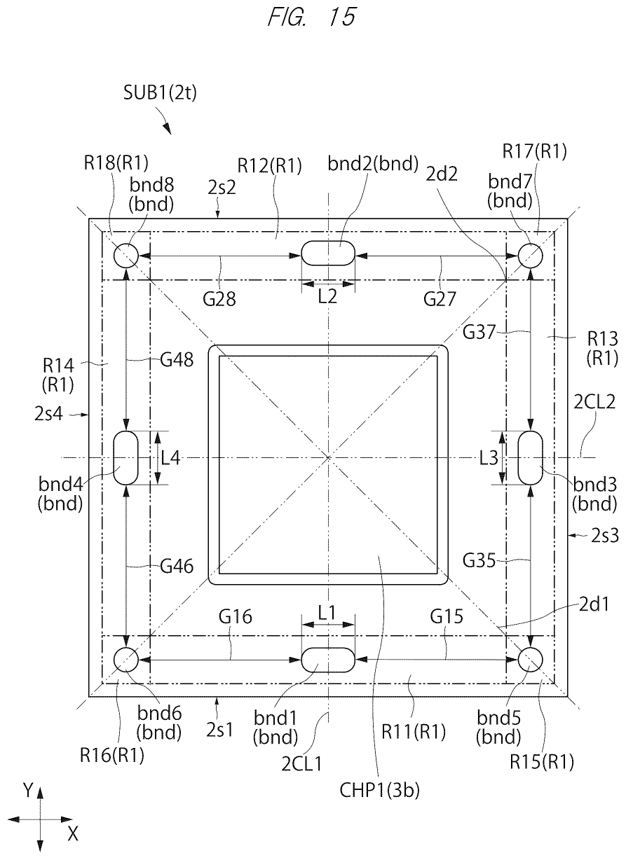

FIG. 15 is a plan view showing a state in which an adhesive is applied on the wiring substate in the adhesive applying step shown by FIG. 13. In an adhesive step, as shown in FIG. 15, an adhesive material bnd is applied at a plurality of portions of a region R1, which is a planned mounting region of the stiffener ring 4 (see FIG. 1), in the upper surface 2t.

In the upper surface 2t of the wiring substrate SUB1, the region R1 has an extension portion R11 extending along the side 2s1, an extension portion R12 extending along the side 2s2, an extension portion R13 extending along the side 2s3, and an extension portion R14 extending along the side 2s4. In addition, the region R1 has a corner portion R15 connected to the extension portion R11 and the extension portion R13, a corner portion R16 connected to the extension portion R11 and the extension portion R14, a corner portion R17 connected to the extension portion R12 and the extension portion R13, and a corner portion R18 connected to the extension portion R12 and the extension portion R14.

When the diagonal line 2d1 explained by using FIG. 1 is drawn, the corner portion R15 and the corner portion R18 are overlapped with the diagonal line 2d1 in the plan view. In addition, when the diagonal line 2d2 is drawn, the corner portion R16 and the corner portion R17 are overlapped with the diagonal line 2d2.

In addition, in the adhesive applying step, a plurality of adhesive materials bnd applied to the region R1 so as to be separated from each other include: an adhesive material bnd1 arranged at a portion overlapping with the extension portion R11 and arranged at a portion overlapping with the center line 2CL1; an adhesive material bnd2 arranged at a portion overlapping with the extension portion R12 and arranged at a portion overlapping with the center line 2CL1; an adhesive material bnd3 arranged at a portion overlapping with the extension portion R13 and arranged at a portion overlapping with the center line 2CL2; and an adhesive material bnd4 arranged at a portion overlapping with the extension portion R14 and arranged at a portion overlapping with the center line 2CL2.

In addition, the plurality of adhesive materials bnd includes: an adhesive bnd5 arranged at a portion overlapping with the corner portion R15 arranged at a portion overlapping with the diagonal line 2d1; an adhesive material bnd6 arranged at a portion overlapping with the corner portion R16 and arranged at a portion overlapping with the diagonal line 2d2; an adhesive material bnd7 arranged at a portion overlapping with the corner portion R17 and arranged at a portion overlapping with the diagonal line 2d2; and an adhesive material bnd8 arranged at a portion overlapping with the corner portion R18 and arranged at a portion overlapping with the diagonal line 2d1.

In addition, in a case of an example shown by FIG. 15, from the viewpoint of the usage amount of the adhesive materials bnd being few, the following expression can be made. That is, the adhesive material bnd1 extends in the X direction. A length L1 of the adhesive material bnd1 in the X direction is shorter than a separate distance G15 between the adhesive material bnd1 and the adhesive material bnd5 in the X direction and a separate distance G16 between the adhesive material bnd1 and the adhesive material bnd6 in the X direction.

In addition, a length L2 of the adhesive layer bnd2 in the X direction is shorter than a separation distance G27 of the adhesive layer bnd2 and the adhesive layer bnd7 in the X direction and a separation distance G28 between the adhesive layer bnd2 and the adhesive layer bnd8 in the X direction. Further, a length L3 of the adhesive layer bnd3 in the Y direction orthogonal to the X direction is shorter than a separation distance G35 of the adhesive layer bnd3 and the adhesive layer bnd5 in the Y direction and a separation distance G37 between the adhesive layer bnd3 and the adhesive layer bnd7 in the Y direction. Moreover, a length L4 of the adhesive layer bnd4 in the Y direction is shorter than a separation distance G46 between the adhesive layer bnd4 and the adhesive layer bnd6 in the Y direction and a separation distance G48 between the adhesive layer bnd4 and the adhesive layer bnd8 in the Y direction.

In addition, in the case of the example of the present embodiment, from the viewpoint of the usage amount of the adhesive layers BND being little, another expression can be made as follows. That is, in the region R1, areas of regions where the plurality of adhesive layers BND are applied in the adhesive material applying step are smaller than areas of regions where the plurality of adhesive materials bnd are not applied. Note that each of the region R2 and the region R3 that have been explained by using FIG. 6 indicates a region obtained after the stiffener ring bonding step and an adhesive curing step shown by FIG. 3 are completed. Accordingly, in the adhesive applying step, the areas of the regions where the plurality of adhesive materials bnd are applied is further shorter than that of the region R2 shown by FIG. 6. Moreover, the areas of the regions where the plurality of adhesive materials bnd are not applied is further larger than that of the region R3 shown by FIG. 6.

Next, in the stiffener ring bonding step shown by FIG. 13, the stiffener ring 4 (see FIG. 1) is arranged on the region R1 shown by FIG. 15, and the stiffener ring 4 is bonded via the plurality of adhesive materials bnd. In this step, each of the plurality of adhesive materials bnd applied on the region R1 is sandwiched between the lower surface of the stiffener ring 4 and the upper surface 2t of the wiring substrate SUB1 and is pushed and spread around them. Consequently, shapes of the plurality of adhesive materials bnd become shapes of a plurality of adhesive layers BND shown by FIG. 4.

Next, in the adhesive curing step shown by FIG. 13, the adhesive materials bnd (see FIG. 15) are cured, thereby making the plurality of adhesive layers BND (see FIG. 4) separated from each other. By this step, the stiffener ring 4 is fixed onto the wiring substrate SUB1. Each of the plurality of adhesive materials bnd shown by FIG. 15 is an organic adhesive containing, for example, a silicon-based thermosetting resin component. In this case, in the adhesive curing step, the wiring substrate SUB1 onto which the stiffener ring 4 (see FIG. 1) is bonded is arranged in a not-shown heating furnace, and each of the plurality of adhesive materials bnd can be cured by heating (cure bake). Note that each of the plurality of adhesive materials bnd may be an organic an epoxy-based thermosetting resin component. Here, an epoxy-based organic adhesive is harder than a silicon-based organic adhesive. Therefore, in comparison with a case of using the silicon-based organic adhesive, the stiffener ring 4 can fixed more firmly to the wiring substrate USB1 and, as a result, the warpage deformation of the wiring substrate SUB1 can be further suppressed.

### <Solder Ball Forming Step>

Next, as a solder ball forming step shown by FIG. 13, as shown in FIG. 2, the plurality of solder balls SB are formed on the lower surface 2b of the wiring substrate SUB1. In this step, the plurality of solder balls SB (see FIG. 2 and FIG. 4) is jointed to the plurality of lands 2LD formed on the lower surface of the wiring substrate SUB1 shown by FIG. 3. After the solder material is arranged on each of the plurality of lands 2LD exposed from the lower surface of the wiring substrate SUB1, the reflow processing is performed. In the solder material, for example, a flux component capable of improving activity of the solder is contained. When the solder material applied on the land 2LD is heated, the flux component seeped out from the solder material activates a surface of the solder material and the solder material can be bonded to the land 2LD. In addition, the solder material is formed in a ball by surface tension of the solder material, and the plurality of solder balls SB shown by FIG. 2 are obtained.

The flux component contained in the solder material may remain as a residue around the solder ball SB by the reflow processing. In this case, by performing the washing step shown by FIG. 13, the residue of the flux component is preferably removed.

### <Washing Step>

Next, as the washing step shown by FIG. 13, the wiring substrate SUB1 is washed. In the washing step, by spraying the washing liquid onto the wiring substrate SUB1, the flux component and the like adhering to the wiring substrate SUB1 or the solder ball SB are removed. At this time, even when the washing liquid is sprayed on a lower surface 2b side of the wiring substrate SUB1 shown by FIG. 3, the washing liquid may wrap around on the upper surface 2t side of the wiring substrate SUB1. In addition, as shown in FIG. 1, the upper surface 2t of the wiring substrate SUB1 is exposed in an inner space of the stiffener ring 4. For this reason, the washing liquid may adhere in the space surrounded by the stiffener ring 4. If the washing liquid remains, an electrical malfunction may occur. By this reason, the washing liquid adhering to the wiring substrate SUB1 in the washing step is preferably removed surely.

### <Washing Liquid Removing Step>

In a washing liquid removing step shown by FIG. 13, the washing liquid adhering to the wiring substrate SUB1 in the above washing step is removed. As described above, in the washing step, the washing liquid may adhere in the space surrounded by the stiffener ring 4 shown by FIG. 1.

However, in the case of the present embodiment, each of the plurality of adhesive layers BND is spaced from each other, so that the washing liquid can be removed from a gap between the plurality of adhesive layers BND adjacent to each other. By this reason, in comparison with a consideration example in which the adhesive layer BND is arranged all around the stiffener ring 4, the washing liquid is easily removed.

In the washing liquid removing step, a method of removing the washing liquid is not limited particularly. For example, a method of applying air (hot air or cold air) to the wiring substrate SUB1, a method of rotating the wiring substrate USB1 to dissipate the washing liquid by a centrifugal force, or a method of drying naturally it can be given.

Among the plurality of embodiments already explained, in the case of the semiconductor device PKG2 shown by FIG. 7, the washing liquid may remain on inner surfaces (surfaces opposite to the semiconductor chip CHP1) of L-shaped adhesive layer BND5, adhesive layer BND6, adhesive layer BND7, and adhesive layer BND8. However, in the case of each embodiment other than the semiconductor device PKG2, such an embodiment has a structure of easily preventing the washing liquid from being accumulated.

Note that the washing liquid removing step can regarded as a part of the washing step shown by FIG. 13.

### <Singularizing Step>

In a case of using a wiring substrate 20 explained by using FIG. 14, as shown by a dotted line in FIG. 13, an singularizing step is performed after the washing step (specifically, after the washing liquid removing step). In the singularizing step, the wiring substrate 20 is cut along a cutting portion 22 shown by FIG. 14, and each of the plurality of device forming portions 21 is singularized. A cutting method is not limited particularly, but, for example, a method of cutting the wiring substrate 20 by a cutting processing using a not-shown dicing plate can be given. Note that in the wiring substrate preparing step shown by FIG. 13, when the wiring substrate USB1 shown by FIG. 1 to FIG. 6 is prepared, the singularizing step can be omitted. This is because the wiring substrate SUB1 shown by FIG. 1 to FIG. 6 corresponds to one piece of the device forming portions 21 shown by FIG. 14.

### Modification Example of Adhesive Applying Step

Next, a modification example with respect to the adhesive applying step explained by using FIG. 15 will be explained. In the respective methods of manufacturing the semiconductor device PKG2 shown by FIG. 7, the semiconductor device PKG3 shown by FIG. 10, and the semiconductor device PKG4 shown by FIG. 11, the shapes of the adhesive materials applied in the adhesive applying step are different. However, even in any case, the area of the adhesive in the plan view is smaller than the area of the adhesive layer BND shown by FIG. 7, FIG. 10, or FIG. 11. This is because, in each method of manufacturing the semiconductor devices, the adhesive is pushed and spread between the stiffener ring and the wiring substrate in the above stiffener ring bonding step.

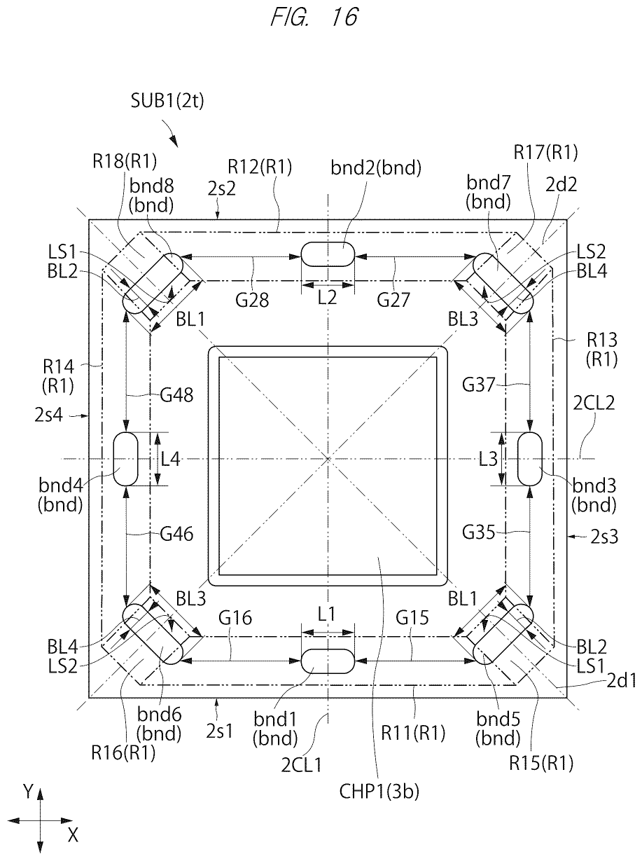

For example, in the method of manufacturing the semiconductor device PKG3 shown by FIG. 10, the plurality of adhesive materials bnd as shown by FIG. 16 are applied. FIG. 16 is a plan view showing a modification example with respect to FIG. 15. In an example shown by FIG. 16, each of the adhesive material bnd5 and the adhesive material bnd8 applied in the adhesive material applying step is set so that a length BL1 in a direction intersecting with the diagonal line 2d1 is longer than a length BL2 in a direction extending along the diagonal line 2d1 in the plan view. In addition, each of the adhesive material bnd6 and the adhesive material bnd7 applied in the adhesive material applying step is set so that a length in a direction intersecting with the second diagonal line is longer than a length in a direction extending along the second diagonal line.

In addition, in the example shown by FIG. 16, in the adhesive applying step, the plurality of adhesive materials bnd are applied as follows. That is, each of the adhesive bnd1 and the adhesive material bnd2 is applied so as to extend in the X direction. Each of the adhesive material bnd3 and the adhesive material bnd4 is applied so as to extend in the Y direction intersecting with the X direction. Each of the adhesive material bnd5 and the adhesive material bnd8 is applied so as to extend in a direction intersecting with the diagonal line 2d1. Each of the adhesive material bnd6 and the adhesive material bnd7 is applied so as to extend in a direction intersecting with the diagonal line 2d2.

In addition, in the example shown by FIG. 16, each application area of the adhesive material bnd5, the adhesive material bnd6, the adhesive material bnd7, and the adhesive material bnd8 is larger than an application area of the adhesive material having the largest application area.

As described above, the invention made by the present inventor has been specifically explained based on the embodiments, but the present invention is not limited to the above embodiments and, needless to say, can be variously modified within a range not departing from the gist thereof.

For example, as a modification example with respect to the stiffener ring 4 shown by FIG. 3, a thickness of the stiffener ring 4 may be smaller than not only a thickness T2 of the wiring substrate SUB1 but also a thickness of the core insulation layer 2CR configurating the wiring substrate SUB1. However, in order to more securely prevent the warpage deformation of the wiring substrate SUB1, it is preferable to arrange the plurality of adhesive layers BND at proper portions and, additionally to this, use the stiffener ring that improves rigidity by increasing their thicknesses.

What is claimed is:

1. A semiconductor device comprising:
a wiring substrate having an upper surface, and a lower surface opposite the upper surface;
a semiconductor chip mounted on the upper surface of the wiring substrate; and
a stiffener ring fixed onto the upper surface of the wiring substrate,
wherein the upper surface has a first side, a second side facing the first side, a third side intersecting with each of the first side and the second side, and a fourth side facing the third side,
wherein in plan view, the stiffener ring is arranged so as to continuously surround around the semiconductor chip, and has: a first extension portion extending along the first side; a second extension portion extending along the second side; a third extension portion extending along the third side; a fourth extension portion extending along the fourth side; a first corner portion connected to the first and third extension portions; a second corner portion connected to each of the first extension portion and the fourth extension portion; a third corner portion connected to each of the second extension portion and the third extension portion; and a fourth corner portion connected to each of the second extension portion and the fourth extension portion,
wherein when a first diagonal line connecting an intersection of the first side and the third side and an intersection of the second side and the fourth side is drawn, the first portion and the fourth corner portion overlap with the first diagonal line,
wherein when a second diagonal line connecting an intersection of the first side and the fourth side and an intersection of the second side and the third side is drawn, the second corner portion and third corner portion overlap with the second diagonal line,
wherein the stiffener ring is fixed onto the upper surface of the wiring substrate between the stiffener ring and the upper surface of the wiring substrate and via a plurality of adhesive layers that is arranged between the stiffener ring and the upper surface of the wiring substrate and that is arranged so as to space the stiffener ring and the wiring substrate apart from each other, and
wherein the plurality of adhesive layers includes:
a first adhesive layer arranged at a portion that is overlapping with the first extension portion, and that is overlapping with a first center line when the first center line connecting a center of the first side and a center of the second side is drawn;
a second adhesive layer arranged at a portion that is overlapping with the second extension portion of the stiffener ring, and that is overlapping with the first center line when the first center line is drawn;
a third adhesive layer arranged at a portion that is overlapping with the third extension portion of the stiffener ring, and that is overlapping with a second center line when the second center line connecting a center of the third side and a center of the fourth side is drawn;
a fourth adhesive layer arranged at a portion that is overlapping with the fourth extension portion of the stiffener ring, and that is overlapping with the second center line when the second center line is drawn;
a fifth adhesive layer arranged at a portion that is overlapping with the first corner portion of the stiffener ring, and that is overlapping with the first diagonal line when the first diagonal line is drawn;
a sixth adhesive layer arranged at a portion that is overlapping with the second corner portion of the stiffener ring, and that is overlapping with the second diagonal line when the second diagonal line is drawn;
a seventh adhesive layer arranged at a portion that is overlapping with the third corner portion of the stiffener ring, and that is overlapping with the second diagonal line when the second diagonal line is drawn; and
an eighth adhesive layer arranged at a portion that is overlapping with the fourth corner portion of the stiffener ring, and that is overlapping with the first diagonal line when the first diagonal line is drawn.

2. The semiconductor device according to claim 1,
wherein a thickness of the stiffener ring is larger than a thickness of the wiring substrate.

3. The semiconductor device according to claim 1,
Wherein, in plan view, a length of each of the fifth adhesive layer and the eighth adhesive layer in a direction intersecting with the first diagonal line is longer than a length of each of the first adhesive layer and the eighth adhesive layer in a direction extending along the first diagonal line, and
Wherein, in plan view, a length of each of the sixth adhesive layer and the seventh adhesive layer in a direction intersecting with the second diagonal line is longer than a length of each of the sixth adhesive layer and the seventh adhesive layer in a direction extending along the second diagonal line.

4. The semiconductor device according to claim 1,
Wherein, in plan view, the first adhesive layer extends in a first direction, and
wherein a length of the first adhesive layer in the first direction is shorter than each of a separation distance between the first adhesive layer and the fifth adhesive layer in the first direction and a separation distance between the first adhesive layer and the sixth adhesive layer in the first direction.

5. The semiconductor device according to claim 4,
Wherein a length of the second adhesive layer in the first direction is shorter than a separation distance between the second adhesive layer and the seventh adhesive layer in the first direction and a separation distance between the second adhesive layer and the eighth adhesive layer in the first direction,
wherein a length of the third adhesive layer in a second direction orthogonal to the first direction is shorter than a separation distance between the third adhesive layer and the fifth adhesive layer in the second direction and a separation distance between the third adhesive layer and the seventh adhesive layer in the second direction in the second direction, and
wherein a length of the fourth adhesive layer in the second direction is shorter than a separation distance between the fourth adhesive layer and the sixth adhesive layer in the second direction and a separation distance between the fourth adhesive layer and the eighth adhesive layer in the second direction.

6. The semiconductor device according to claim 1,
wherein the upper surface of the wiring substrate has a first region overlapping with the stiffener ring in plan view, and
wherein an area of a second region, in which the wiring substrate and the stiffener ring oppose to each other via the plurality of adhesive layers, in the first region is smaller than an area of a third region in which the wiring substrate and the stiffener ring oppose to each other without going through the plurality of adhesive layers.

7. The semiconductor device according to claim 1,
wherein a contact area in which each of the fifth adhesive layer, the sixth adhesive layer, the seventh layer, and the eighth adhesive layer contacts with the wiring substrate is larger than a contact area of the adhesive layer, which has a largest contact area with the wiring substrate, among the first adhesive layer, the second adhesive layer, the third adhesive layer, and the fourth adhesive layer.

8. The semiconductor device according to claim 1,
Wherein, in plan view, each of the fifth adhesive layer and the eighth adhesive layer has a long side opposing to the semiconductor chip and extending in a direction intersecting with the first diagonal line, and
Wherein, in plan view, each of the sixth adhesive layer and the seventh adhesive layer has a long side opposing to the semiconductor chip and extending in a direction intersecting with the second diagonal line.

9. The semiconductor device according to claim 1,
wherein the semiconductor chip has a first surface, a plurality of protrusion electrodes formed on the first surface, and a second surface opposite to the first surface, and is mounted on the wiring substrate via the plurality of protrusion electrodes so that the first surface opposes to the upper surface of the wiring substrate.

10. The semiconductor device according to claim 1,
wherein a plurality of solder balls is formed on the lower surface of the wiring substrate.

11. The semiconductor device according to claim 1,
Wherein, in plan view, an electronic component mounted on the wiring substrate is arranged between the semiconductor chip and the stiffener ring.

12. A method of manufacturing a semiconductor device, the method comprising:
(a) mounting a semiconductor chip on an upper surface of a wiring substrate; and
(b) mounting a stiffener ring on the upper surface of the wiring substrate,
wherein the (b) includes:
(b1) applying adhesive materials at plurality of portions of a first region, which is a planned mounting region of the stiffener ring, in the upper surface;
(b2) arranging the stiffener ring on the first region to bond the stiffener ring via the adhesive materials; and
(b3) curing the adhesive materials to make the cured adhesive materials a plurality of adhesive layers separated from each other, thereby fixing the stiffener ring onto the wiring substrate,
wherein the upper surface of the wiring substrate has a first side, a second side opposite to the first side, a third side intersecting with the first side and the second side, and a fourth side opposite to the third side,
wherein the first region in the upper surface of the wiring substrate continuously surrounds around a region on which the semiconductor chip is mounted, and the first region has: a first extension portion extending along the first side; a second extension portion extending along the second side; a third extension portion extending along the third side; a fourth extension portion extending along the fourth side; a first corner portion connected to the first extension portion and the third extension portion; a second corner portion connected to the first extension portion and the fourth extension portions; a third corner portion connected to the second extension portion and the third extension portion; and a fourth corner portion connected to the second extension portion and the fourth extension portion,
wherein when a first diagonal line connecting an intersection of the first side and the third side and an intersection of the second side and the fourth side is drawn, the first center portion and the fourth corner portion overlap with the first diagonal line,
wherein when a second diagonal line connecting an intersection of the first side and the fourth side and an intersection of the second side and the third side is drawn, the second corner portion and the third corner portion overlap with the second diagonal line,
wherein in the (b1), a plurality of adhesive materials applied onto the first region so as to be separated from each other include:
a first adhesive material arranged at a portion that is overlapping with the first extension portion, and that is overlapping with a first center line when the first center line connecting a center of the first side and a center of the second side is drawn;
a second adhesive material arranged at a portion that is overlapping with the second extension portion, and that is overlapping with the first center line when the first center line is drawn;
a third adhesive material arranged at a portion that is overlapping with the third extension portion, and that is overlapping with a second center line when the second center line connecting a center of the third side and a center of the fourth side is drawn;
a fourth adhesive material arranged at a portion that is overlapping with the fourth extension portion, and that is overlapping with the second center line when the second center line is drawn;
a fifth adhesive material arranged at a portion that is overlapping with the first corner portion, and that is overlapping with the first diagonal line when the first diagonal line is drawn;
a sixth adhesive material arranged at a portion that is overlapping with the second corner portion, and that is overlapping with the second diagonal line when the second diagonal line is drawn;
a seventh adhesive material arranged at a portion that is overlapping with the third corner portion, and that is overlapping with the second diagonal line when the second diagonal line is drawn; and
an eighth adhesive material arranged at a portion that is overlapping with the fourth corner portion, and that is overlapping with the first diagonal line when the first diagonal line is drawn.

13. The method of manufacturing a semiconductor device according to claim 12,
Wherein a thickness of the stiffener ring is larger than a thickness of the wiring substrate.

14. The method of manufacturing a semiconductor device according to claim 12,
Wherein, in plan view, each of the fifth adhesive material and the eighth adhesive material applied in the (b1) is set so that a length in a direction intersecting with the first diagonal line is longer than a length in a direction extending along the first diagonal line, and
Wherein, in plan view, each of the sixth adhesive material and the seventh adhesive material applied in the (b1) is set so that a length in a direction intersecting with the second diagonal line is longer than a length in a direction extending along the second diagonal line.

15. The method of manufacturing a semiconductor device according to claim 12,
wherein the first adhesive material applied in the (b1) extends in a first direction, and
wherein after the (b1), a length of the first adhesive material in the first direction is shorter than a separation distance between the first adhesive material and fifth adhesive material in the first direction and a separation distance between the first adhesive material and the sixth adhesive material in the first direction.

16. The method of manufacturing a semiconductor device according to claim 15,
wherein after the (b1), a length of the second adhesive material in the first direction is shorter than a separation distance between the second adhesive material and the seventh adhesive material in the first direction and a separation distance between the second adhesive material and the eighth adhesive material in the first direction,
wherein after the (b1), a length of the third adhesive material in a second direction orthogonal to the first direction is shorter than a separation distance between the third adhesive material and the fifth adhesive material in the second direction and a separation distance between the third adhesive material and the seventh adhesive material in the second direction, and
wherein after the (b1), a length of the fourth adhesive material in the second direction is shorter than a separation distance between the fourth adhesive material and the sixth adhesive material in the second direction and a separation distance of the fourth adhesive material and the eighth adhesive material in the second direction.

17. The method of manufacturing a semiconductor device according to claim 12,
wherein an area of a region, in which the adhesive materials are applied in the (b1), in the first region is smaller than an area of a region in which the adhesive materials are not applied in the (b1).

18. The method of manufacturing a semiconductor device according to claim 12,
wherein an application area of each of the fifth adhesive material, the sixth adhesive material, the seventh adhesive material, and the eighth adhesive material is larger than an application area of the adhesive layer, which has a largest application area, among the first adhesive material, the second adhesive material, the third adhesive material, and the fourth adhesive material.

19. The method of manufacturing a semiconductor device according to claim 12,
wherein in the (b1), each of the first adhesive material and the second adhesive material s is applied so as to extend in a first direction,
wherein in the (b1), each of the third adhesive material and the fourth adhesive material is applied so as to extend in a second direction intersecting with the first direction,
wherein in the (b1), each of the fifth adhesive material and the eighth adhesive material is applied so as to extend in a direction intersecting with the first diagonal line, and
wherein in the (b1), each of the sixth adhesive material and the seventh adhesive material is applied so as to extend in a direction intersecting with the second diagonal line.

20. The method of manufacturing a semiconductor device according to claim 12, further comprising:
(c) after the (b), forming a plurality of solder balls on a lower surface opposite to the upper surface of the wiring substrate; and
(d) after the (c), washing the wiring substrate.
